(19) United States
(12) Patent Application Publication
(10) Pub. No.: US 2026/0304743 A1
(43) Pub. Date: Oct. 1, 2026

(54) SEMICONDUCTOR DEVICE, MANUFACTURING METHOD, AND MEMORY SYSTEM

(71) Applicant: Yangtze Memory Technologies Co., Ltd., Wuhan (CN)

(72) Inventors: Kailang XU, Wuhan (CN); Bin YUAN, Wuhan (CN); Wei XU, Wuhan (CN); Wenbin ZHOU, Wuhan (CN); Zongliang HUO, Wuhan (CN)

(21) Appl. No.: 19/344,388

(22) Filed: Sep. 29, 2025

(30) Foreign Application Priority Data
Mar. 26, 2025 (CN) 202510368808.3

(51) Int. Cl. H10B 12/00

(52) U.S. Cl. CPC H10B 12/315; H10B 12/05; H10B 12/50

(57) ABSTRACT

A semiconductor device includes: first semiconductor bodies extending along a first direction, a first semiconductor body having a first end and a second end opposite to each other along the first direction; conductive layers extending along a second direction and located between adjacent first semiconductor bodies in a third direction; and a first contact structure located on a side close to the first end of the first semiconductor body in the first direction. The second direction intersects with the third direction, and a plane formed by the second and third directions intersects with the first direction. An end of the first contact structure close to the first semiconductor body is located between adjacent conductive layers. Sidewalls of the first contact structure extending along the first direction overlap at least partially with the conductive layer in the third direction, and are connected to the conductive layer.

### CROSS-REFERENCE TO RELATED APPLICATIONS

This application claims priority to Chinese Patent Application No. 202510368808.3, filed on Mar. 26, 2025, which is hereby incorporated by reference in its entirety.

### TECHNICAL FIELD

Implementations of the present disclosure relate to the field of semiconductor technology, and particularly to a semiconductor device and its manufacturing method, and a memory system.

### BACKGROUND

Memory apparatuses are storage devices used in modern information technology to save information. Some semiconductor memory devices, including non-volatile memories and volatile memories, have gradually become mainstream products in the storage market due to their high storage density, controllable production cost, suitable read and write speed, and retention characteristics. However, as people's requirements for storage devices continue to increase, there is much room for improvement in memory devices and their manufacturing methods.

### SUMMARY

According to some aspects of implementations of the present disclosure, a semiconductor device is provided, comprising: first semiconductor bodies extending along a first direction, wherein the first semiconductor body has a first end and a second end arranged opposite to each other along the first direction; conductive layers extending along a second direction, wherein the conductive layer is located between the first semiconductor bodies that are adjacent in a third direction, the second direction intersects with the third direction, and a plane formed by the second and third directions intersects with the first direction; and a first contact structure located on a side close to the first end of the first semiconductor body in the first direction, wherein an end of the first contact structure close to the first semiconductor body is located between adjacent ones of the conductive layers, and sidewalls of the first contact structure extending along the first direction overlap at least partially with the conductive layer in the third direction, and are connected to the conductive layer.

According to some aspects of implementations of the present disclosure, a manufacturing method of a semiconductor device is provided, comprising:

forming first semiconductor bodies extending along a first direction, wherein the first semiconductor body has a first end and a second end arranged opposite to each other along the first direction;

forming conductive layers extending along a second direction, wherein the conductive layer is located between the first semiconductor bodies that are adjacent in a third direction, the conductive layer protrudes from the first end along the first direction, the second direction intersects with the third direction, and a plane formed by the second and third directions intersects with the first direction; and

forming a first contact structure on the first end of the first semiconductor body, wherein an end of the first contact structure close to the first semiconductor body is located between adjacent ones of the conductive layers, and a sidewall of the first contact structure extending along the first direction is connected to the conductive layer. According to some aspects of implementations of the present disclosure, a memory system is provided, comprising one or more of the semiconductor devices described above; and a memory controller coupled to and controlling the semiconductor devices.

An implementation of the present disclosure provides a semiconductor device, comprising: first semiconductor bodies extending along a first direction, wherein the first semiconductor body has a first end and a second end arranged along the first direction; conductive layers extending along a second direction and located between the first semiconductor bodies that are adjacent; and a first contact structure close to the first end of the first semiconductor body in the first direction, wherein an end of the first contact structure close to the first semiconductor body is located between adjacent ones of the conductive layers, sidewalls of the first contact structure extending along the first direction overlap at least partially with the conductive layer along the third direction for connection. Therefore, the conductive layer may be used for supplying power to or leading out an electric signal from a device (such as a capacitor and the like) connected with the first contact structure. Compared with the scheme that the first semiconductor body supplies power to or leads out from the first contact structure, the conductive layer is beneficial for reducing resistance and improving electrical connection stability, and may bear larger voltage and current loads.

### BRIEF DESCRIPTION OF THE DRAWINGS

FIG. 1 is a schematic diagram of a memory array illustrated according to an example implementation;

FIGS. 2 to 14 are schematic diagrams of semiconductor structures illustrated according to implementations of the present disclosure;

FIG. 15 is a schematic flow chart of a manufacturing method of a semiconductor device illustrated according to implementations of the present disclosure;

FIGS. 16 to 28 are schematic diagrams of a manufacturing method of a semiconductor device illustrated according to implementations of the present disclosure; and

FIGS. 29 and 30 are diagrams of example systems illustrated according to implementations of the present disclosure.

### DETAILED DESCRIPTION

Example implementations disclosed in the present disclosure will be described in more detail below with reference to the accompanying drawings. It should be understood that when an element or layer is referred to as "on", "adjacent to", "connected to", or "coupled to" other elements or layers, it may be directly on, adjacent to, connected to, or coupled to other elements or layers, or there may be intermediate elements or layers. On the contrary, when an element is referred to as "directly on", "directly adjacent to", "directly connected to", or "directly coupled to" other elements or layers, there are no intervening elements or layers.

Spatial relationship terms such as "below", "under", "lower", "beneath", "over", "above", etc. may be used herein for ease of description to describe the relationship of an element or feature with respect to other elements or features shown in the figures. It should be understood that in addition to orientations shown in the figures, the spatial relationship terms intend to include different orientations of the devices in use and operation. For example, if a device in the figures is flipped, then an element or feature described as "below" or "under" or "beneath" other elements will be oriented "on" other elements or features. Therefore, the example terms "below" and "under" may include both upper and lower orientations. The device may be otherwise oriented (rotated 90 degrees or at other orientations) and spatial descriptors used herein are explained accordingly.

The terms used herein are only for the purpose of describing example implementations and are not intended as a limitation of the present disclosure. When used herein, the singular forms of "a", "an", and "the/said" are also intended to include the plural form, unless the context clearly indicates otherwise. It should also be understood that the terms "comprising" and/or "including", when used in the present specification, determine the presence of the described features, integers, steps, operations, elements, and/or components, but do not exclude the presence or addition of one or more other features, integers, steps, operations, elements, components, and/or groups. When used herein, the term "and/or" includes any and all combinations of the related listed items.

It should be understood that the term "some implementations" or "an implementation" mentioned throughout the specification means that particular features, structures, or characteristics related to the implementations are included in at least one implementation of the present disclosure. Therefore, the phrases "in some implementations" or "in an implementation" that appear throughout the specification may not necessarily refer to the same implementation. In addition, these particular features, structures, or characteristics may be combined in any suitable manner in one or more implementations. It should be understood that in various implementations of the present disclosure, the size of the sequence numbers of the above processes does not imply the order of execution. The order of execution of each process should be determined by its function and internal logic, and should not constitute any limitation on the implementation process of implementations of the present disclosure.

Some semiconductor devices, such as memory devices, may be Dynamic Random Access Memories (DRAMs), which may include a memory array and a peripheral circuit. The peripheral circuit may control the memory array and operate the memory array to perform read, write, or refresh operations. A semiconductor device or memory device provided in an implementation of the present disclosure may be a memory apparatus or a part of a memory apparatus. The semiconductor device may be a DRAM, or at least part of the memory devices in a DRAM, or the memory apparatus includes a DRAM, which includes the memory device disclosed in the present disclosure, which may be applied to a double data rate synchronous dynamic random access memory using DDR4 memory specification and DDR5 memory specification, and a low power consumption double data rate synchronous dynamic random access memory using LPDDR5 memory specification.

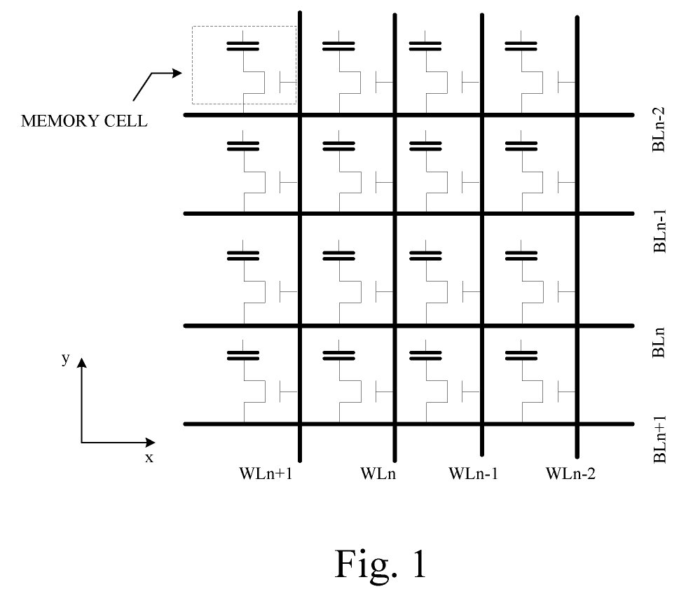

In a DRAM, a memory array may be arranged in rows and columns, so that a memory cell may be addressed by specifying a row and column of its array. The memory array includes a plurality of word lines corresponding to rows and a plurality of bit lines corresponding to columns. The word lines and bit lines intersect, and a memory cell at the intersection of a selected word line and a selected bit line is selected to perform read, write, or refresh operations. As shown in FIG. 1, the memory array may include a plurality of word lines WLn, WLn+1, WLn-1, and WLn-2, and a plurality of bit lines BLn, BLn+1, BLn-1, and BLn-2, and the word lines and bit lines intersect. Memory cells in the memory array may include capacitors and transistors, and one memory cell may include one transistor and one capacitor. The word line may also be a conductive structure such as a gate layer, etc., which serves as the gate of the transistor. One controlled end (source) of the transistor is coupled to one electrode of the capacitor, and the other controlled end (drain) of the transistor is coupled to the bit line. The other electrode of the capacitor may be grounded or applied with another voltage (such as Vcc/2). As shown in FIG. 1, the memory array is arranged in x columns and y rows, in which the columns and rows may or may not be vertical. A z-direction is a vertical direction or a thickness direction of a device, which may be a first direction in an implementation of the present disclosure. The xoy plane intersects and is perpendicular to the z-direction. The y-direction may be a second direction in the implementation of the present disclosure, and the x-direction may be a third direction in the implementation of the present disclosure. The extension direction of the word lines or rows may be parallel to the y-direction or have an angle with the y-direction, while the extension direction of the bit lines or columns may be parallel to the x-direction or have an angle with the x-direction. An orthographic projection of the word line on the xoy plane is perpendicular to an orthographic projection of the bit line on the xoy plane, or the orthographic projection of the word line on the xoy plane is not perpendicular to the orthographic projection of the bit line on the xoy plane, but has a certain angle.

In some implementations, when performing read or write operations, a corresponding word line may be selected using a word line selection signal, and a corresponding bit line may be selected based on a column selection signal. The simultaneous select of the word line and bit line may locate a selected memory cell. At this time, a transistor of the selected memory cell is turned on due to an operating voltage applied by the word line, so that read, write, or refresh operations may be performed on the selected memory cell. In some implementations, the capacitors may be replaced with other memory structures, including but not limited to a phase change memory structure, a resistive change memory structure, or a magnetic change memory structure.

In some implementations, a capacitor represents logical 1 and 0 by the amount of charge stored therein, or the high and low voltage difference across the capacitor. A voltage signal on the word line is applied to the gate to control the transistor to turn on or off, achieving the select and non-select of the capacitor, so that data information stored in the capacitor is read through the bit line, or the data is written into the capacitor through the bit line for storage.

In some implementations, a DRAM memory device or DRAM memory apparatus further comprises a peripheral circuit coupled to the memory array of FIG. 1. For example, the peripheral circuit may include but is not limited to: a sensing amplification circuit, a row decoding circuit, a column decoding circuit, a voltage generation circuit, etc. The sensing amplification circuit is coupled to the bit line, and may be configured to capture weak voltage fluctuations on the bit line and locally restore voltages of the capacitor of the memory cell based on the voltage fluctuations. The sensing amplification circuit may include a latch that may latch the restored capacitor voltage values, so that information stored in the memory cell is transferred from the capacitor to the amplification circuit. The sensing amplification circuit may include a differential sensing amplification circuit, which is coupled to two bit lines and operates using a selected bit line and a complementary bit line used as a reference line to detect and amplify a voltage difference on a pair of bit lines. The row decoding circuit is configured to address the memory array and apply an operating voltage to the word line. The column decoding circuit is configured to perform column addressing on the memory array, applying or receiving the bit line voltages. The voltage generation circuit generates required high and low voltages for each device.

In some implementations, the peripheral circuit may include a CMOS structure or a CMOS circuit, including a digital or analog circuit formed by transistors, to control or power the memory array. Improving device integration of the peripheral circuit is beneficial for improving the integration of the overall memory devices, and improving the stability of devices in the peripheral circuit is beneficial for improving the operational stability of the memory devices.

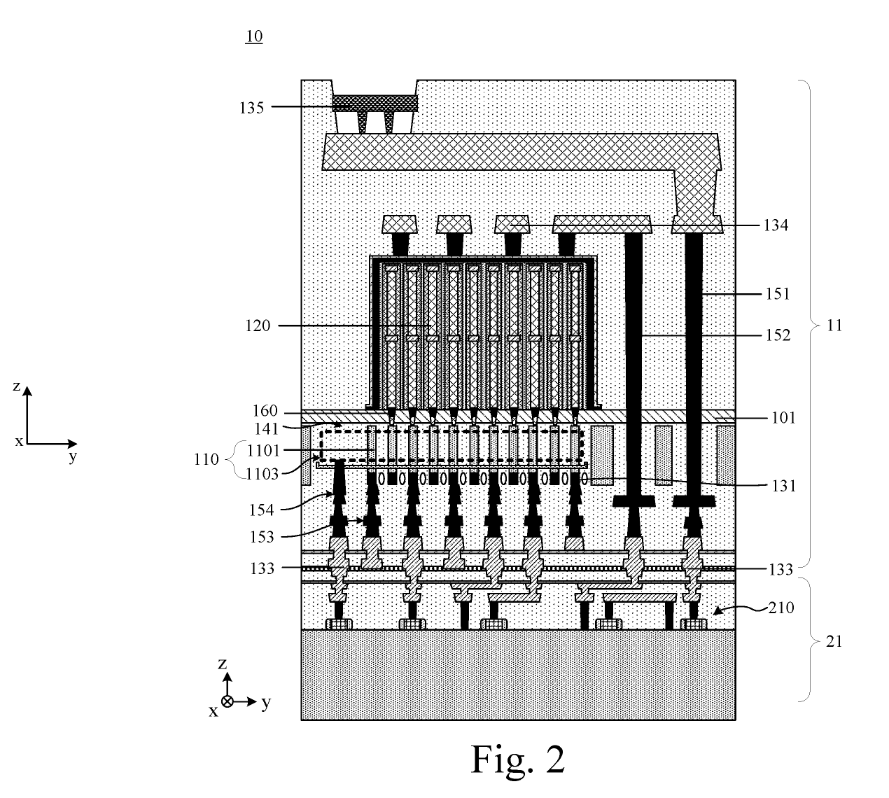

According to some aspects of implementations of the present disclosure, FIG. 2 provides a semiconductor device 10 (or memory device) comprising a first semiconductor structure 11 and a second semiconductor structure 21 stacked in a first direction. The first semiconductor structure 11 and the second semiconductor structure 21 are connected by bonding and electrically interconnected through a plurality of bonding contacts 133 at a bonding interface. The bonding may include hybrid bonding. Alternatively, the first semiconductor structure 11 and the second semiconductor structure 21 may not be connected by bonding. For example, the first semiconductor structure 11 may be formed on the second semiconductor structure 21.

The first semiconductor structure 11 in FIG. 2 may include a memory array, and the second semiconductor structure 21 may include a peripheral circuit 210 coupled (electrically connected) to the memory array. The peripheral circuit 210 controls operations of the memory array, such as read, write, or refresh, etc. The memory array may be a DRAM memory cell array, which may include a plurality of DRAM memory cells. The semiconductor device 10 may be used as a DRAM memory device or at least a part of a DRAM memory apparatus. For example, the first semiconductor structure 11 may include a plurality of transistors 110, or arrays of a plurality of transistors 110 arranged in an array along the x-direction and y-direction, and capacitor structures 120 located on the transistors 110, in which the capacitor structure 120 may be configured to store data or may be configured as a storage capacitor for storing data. Some capacitor structures 120 in the first semiconductor structure 11 may be configured as decoupling capacitors or denoising capacitors, which may be used to reduce signal noise interference and increase power supply and signal interconnection stability, and coupled to the peripheral circuit 210 through connection structures, interconnect layers, and bonding contacts 133.

In some implementations, the first semiconductor structure 11 may include a capacitor array formed by a plurality of capacitor structures 120. The capacitor array may include a plurality of first capacitor structures 121 and a plurality of second capacitor structures 122. The second capacitor structure 122 may serve as a storage capacitor, while the first capacitor structure 121 serves as a decoupling capacitor. The first capacitor structure 121 is located at an edge region of the storage capacitor array formed by the second capacitor structure 122, for example, an edge region on a side of the storage capacitor array in the x or y-direction. In some implementations, device structures of the second capacitor structure 122 and the first capacitor structure 121 may be the same or different.

Implementations of the present disclosure do not limit the specific structure of the capacitor structure 120. The capacitor structure 120 may include a first electrode, a dielectric layer, and a second electrode. The dielectric layer electrically isolates the first electrode and the second electrode. One electrode in the capacitor structure 120 may extend along the z-direction and have a cylindrical shape.

In some implementations, the first semiconductor structure 11 of FIG. 2 may include a transistor 110, which may include a semiconductor body 1101 extending along the z-direction. The semiconductor body 1101 may have a first end and a second end arranged opposite to each other along the z-direction. The first end and the second end may be doped to form a first active region and a second active region, respectively. The first end and the second end may serve as a source and drain, respectively, positions of which may be interchanged. The first end may be an upper end of the semiconductor body 1101, and the second end may be a lower end of the semiconductor body 1101. A region between the first end and the second end may serve as a channel region of the transistor 110. The channel region may be doped, and the doping type is opposite to that of the first end. The transistor 110 may include a gate layer 1103 extending along the y-direction and covering the channel region of the semiconductor body 1101. The transistor 110 may also include a portion of the gate layer 1103 that overlaps a first semiconductor body 1111 in the x-direction. The gate layer 1103 may serve as a word line. The gate layer 1103 is obscured due to the schematic angle of the cross-section, and its extension position is indicated by a dashed box in the figure.

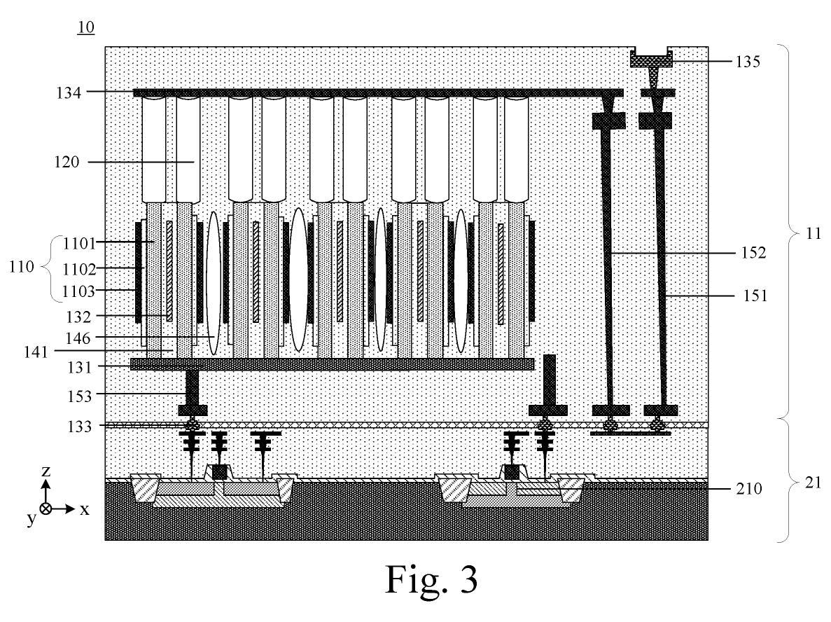

Referring to FIG. 2, the first semiconductor structure 11 further includes: a bit line 131 coupled to the second end of the semiconductor body 1101, which extends along the x-direction; a contact structure 160 coupled to the first end of the semiconductor body 1101; and a capacitor structure 120 located on an end of the contact structure 160 away from the semiconductor body 1101. A part of the capacitor structure 120 serves as a storage capacitor, and another part of the capacitor structure 120 may serve as a decoupling capacitor. By selecting the gate layer 1103 and the bit line 131, the semiconductor body 1101 corresponding to both the gate layer 1103 and the bit line 131 may be selected, such that the semiconductor body 1101 is turned on to select the capacitor structure 120, and the capacitor structure 120 may be charged and discharged or the amount of charge may be sensed to perform operations such as write, refresh, or read. The semiconductor body 1101 and capacitor structure 120 may be illustrated in FIG. 3 below.

In some implementations, a dielectric material (or an isolation material 141 in FIG. 3) may be filled between adjacent semiconductor bodies 1101 to electrically isolate the semiconductor bodies 1101. The isolation material 141 may include an air gap 146 to reduce parasitic capacitance between the semiconductor bodies 1101. A first dielectric layer 101 is disposed on the semiconductor body 1101 and the isolation material 141 between the semiconductor bodies 1101, and the contact structure 160 penetrates through the first dielectric layer 101 and is connected to the first end of the semiconductor body 1101. The isolation material 141 and the first dielectric layer 101 between the semiconductor body 1101 may be the same or different. With respect to the etching of the semiconductor body 1101, the first dielectric layer 101 may have a different etching selectivity ratio from the isolation material 141, and the first dielectric layer 101 has higher etching resistance compared to the semiconductor body 1101. For example, the isolation material 141 may be silicon oxide, and the first dielectric layer 101 may be silicon nitride. When composition materials of the first dielectric layer 101 and the isolation material 141 are the same or similar, there may not be a physical boundary between dielectric film layers with the same or similar composition.

In some implementations, the second semiconductor structure 21 bonded with the first semiconductor structure 11 is located on a side of the bit line 131 away from the semiconductor body 1101. Before bonding, surfaces to be bonded of the first semiconductor structure 11 and the second semiconductor structure 21 have a first bonding contact and a second bonding contact, respectively, which lead electrical signals of the semiconductor structures to the surfaces to be bonded, respectively. The surface to be bonded of the first semiconductor structure 11 is at the side of the bit line 131 away from the capacitor structure 120 and has a certain distance from the bit line 131. The bonding contact 133 may include structures such as solder pads and conductive plugs. The surfaces to be bonded of the first semiconductor structure 11 and the second semiconductor structure 21 are bonded, and the interface where the two surfaces to be bonded are in contact is a bonding interface. The first and second bonding contacts are in contact and bonded at the bonding interface, achieving electrical signal interconnection between the first semiconductor structure 11 and the second semiconductor structure 21. The first and second bonding contacts may not have a physical boundary therebetween after bonding, and may be regarded as a bonding contact 133. The bonding contact 133 penetrates through the bonding interface, which is a dielectric layer. A portion of the bonding contact 133 located at the first semiconductor structure is the first bonding contact before bonding, and a portion of the bonding contact 133 located at the second semiconductor structure is the second bonding contact before bonding. The bonding contact 133 leads an electrical signal of the first semiconductor structure 11 to the bonding interface, for electrical interconnection with the second semiconductor structure 21. The memory array in the first semiconductor structure 11 may be coupled to the bonding contact 133 through a wiring layer or a connection structure, for electrical interconnection with the peripheral circuit 210 of the second semiconductor structure 21.

In some implementations, the semiconductor device 10 or the first semiconductor structure 11 may include a solder pad 135, which is coupled to a connection structure 151 extending along the z-direction, and the connection structure 151 is coupled to the bonding contact 133. Alternatively, the solder pad 135 may be coupled to the connection structure 151 through an interconnect layer, which may be a redistribution layer. The solder pad 135 may serve as an IO interface for powering and communicating with semiconductor device 10. A plurality of capacitor structures 120 may be coupled to the bonding contact 133 at least through the connection structure 152. The plurality of capacitor structures 120 may be coupled through the interconnect layer 134. The interconnect layer 134 is connected to the peripheral circuit 210 through the connection structure 152 and the bonding contact 133, and may be grounded or connected to other common voltage terminals. The bit line 131 may be coupled to the bonding contact 133 at least through the connection structure 153. An interconnect layer may be disposed and coupled between the connection structure 153 and the bonding contact 133. The gate layer 1103 may be coupled to the peripheral circuit 210 at least through the connection structure 154 and the bonding contact 133. The interconnect layer mentioned in implementations of the present disclosure may be located at different film layers of the semiconductor structure, and may include a wiring layer, a circuit layer, or a plurality of wiring layers stacked and coupled through a conductive via and a conductive plug. The connection structure may include a conductive plug, a conductive via, or a plurality of stacked and coupled conductive plugs.

In some other implementations, the second semiconductor structure 21 and the first semiconductor structure 11 may not be connected by bonding. The second semiconductor structure 21 is formed on a side of the bit line 131 of the first semiconductor structure 11 away from the semiconductor body 1101, and the bonding contact 133 serves as a conductive contact or connection structure, or the bonding contact 133 is not disposed.

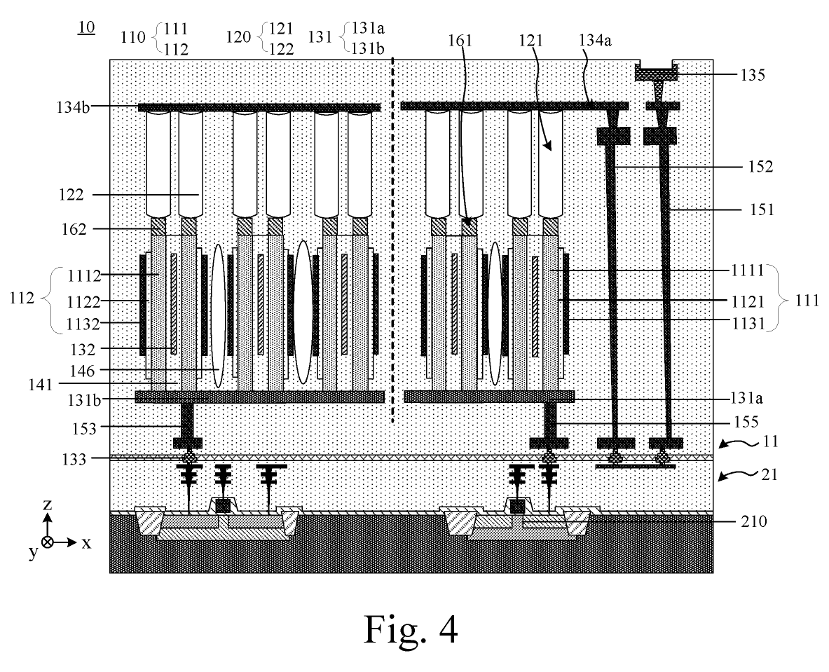

In some implementations, FIG. 3 illustrates a plurality of capacitor structures 120 for storage capacitors, and a transistor 110 coupled to the capacitor structures 120. The capacitor structures 120 may be connected to and in direct contact with the transistor 110 or coupled through the contact structure 160. The transistor 110 may include at least the semiconductor body 1101, the gate layer 1103, and a gate dielectric layer 1102 located between the semiconductor body 1101 and the gate layer 1103. FIG. 4 illustrates a plurality of capacitor structures 120, which are coupled to the transistor 110 through the contact structure 160. A portion of the capacitor structures 120 are employed as decoupling capacitors, such as the first capacitor structure 121. Another portion of the capacitor structures 120 are employed as storage capacitors, such as the second capacitor structure 122. The first capacitor structure 121 is located at an edge region of the second capacitor structure 122 in the x-direction. The second capacitor structure 122 may be replaced with a phase change memory structure, a resistive change memory structure, and a magnetic change memory structure to constitute other memory devices.

As shown in FIG. 4, taking the second capacitor structure 122 as an example, the second capacitor structure 122 is coupled to the second transistor 112. The second transistor 112 includes: a second semiconductor body 1112 extending along the z-direction; a gate layer 1132 extending along the y-direction, which in an example includes a portion where the gate layer 1132 overlaps with the second semiconductor body 1112; and a gate dielectric layer 1122 located between sidewalls of the gate layer 1132 and the second semiconductor body 1112. The first and second ends of the second semiconductor body 1112 in the z-direction serve as a source or drain, respectively. A second contact structure 162 is disposed on the first end to couple the second capacitor structure 122, and the second end is coupled to the bit line 131. The gate layer 1132 covers sidewalls between the first end and the second end of the second semiconductor body 1112. The gate layer 1132 serves as the control gate of the second transistor 112 to control the turn-on and turn-off of the second transistor 112. The shape of the cross-section of the second semiconductor body 1112 in the xoy plane may include but is not limited to: rectangular, quadrilateral, other polygonal shapes; circular, elliptical, or other irregular shapes, etc., which is not limited in the present disclosure.

The isolation material 141 (or the dielectric material) may be filled between adjacent second transistors 112 to form an isolation structure. The isolation material 141 may include or enclose an air gap 146 to reduce parasitic capacitance. The conductive structure 132 may be disposed between the adjacent second semiconductor bodies 1112 to reduce crosstalk between the adjacent gate layers 1132. The conductive structure 132 and the gate layer 1132 may be disposed on two opposite sides of the second semiconductor body 1112 in the x-direction. When the gate layer 1132 is applied with a turn-on voltage of the transistor 110, the conductive structure 132 may be grounded or connected to a fixed voltage (such as a negative voltage) to reduce the crosstalk between the transistors 110. The fixed voltage may be a fixed voltage value calibrated during the factory testing phase of the memory device, or a calibrated voltage interval. For example, taking two adjacent conductive structures 132 as an example, two second semiconductor bodies 1112 may be disposed between the two adjacent conductive structures 132. Two gate layers 1132 in face-to-face configuration are disposed between the two second semiconductor bodies 1112, and an air gap 146 is disposed between the two gate layers 1132 in face-to-face configuration.

One second semiconductor body 1112 in FIGS. 3 and 4 may correspond to one gate layer 1132, and two second semiconductor bodies 1112 may share one conductive structure 132. In other implementations, in order to increase the gate control performance of the second semiconductor body 1112, one second semiconductor body 1112 may be disposed with two gate layers 1132, or a gate all around layer may be disposed around sidewalls of the second semiconductor body 1112. In order to improve the integration of memory devices and reduce parasitic capacitance and resistance, the conductive structure 132 may also have other arrangements, such as one second semiconductor body 1112 may correspond to one conductive structure 132.

In some implementations, a side of the first end of the second semiconductor body 1112 close to the bit line 131 may be heavily doped or formed with a metal silicide to reduce the contact resistance between the second semiconductor body 1112 and the bit line 131. The bit line 131 may include a metal conductive material or a metal semiconductor compound. For example, the second semiconductor body 1112 may include silicon, and the bit line 131 may include metal silicide such as tungsten silicide or titanium silicide; or a metal silicide layer and a metal layer deposited on a side of the metal silicide layer away from the second semiconductor body 1112 may be included to constitute the bit line 131. The metal layer may include but is not limited to tungsten, copper, aluminum, etc.

In some implementations, the second contact structure 162 may be disposed between the second capacitor structure 122 and the second semiconductor body 1112, and the second semiconductor body 1112 is coupled to the second capacitor structure 122 through the second contact structure 162. The second contact structure 162 may include a metal silicide to reduce the contact resistance between the second semiconductor body 1112 and the second capacitor structure 122 and improve adhesion, such as titanium silicide. The second contact structure 162 may include a multi-layer structure, in which a portion close to the second semiconductor body 1112 and a portion in contact with the second semiconductor body 1112 may include metal silicide to reduce contact resistance and improve adhesion, and a portion in contact with the second capacitor structure 122 may include metal to improve electrical connection performance.

For example, the second semiconductor body 1112 may include but is not limited to: elemental semiconductor materials (such as silicon, germanium), III-V compound semiconductor materials, II-VI compound semiconductor materials, organic semiconductor materials, or other semiconductor materials known in the art, e.g., silicon, germanium, or silicon carbide, etc. For example, the second semiconductor body 1112 may also include materials such as indium gallium zinc oxide (IGZO), etc. An IGZO material may include oxides of elements such as indium, gallium, and zinc, etc., and have excellent semiconductor properties. The addition of indium and gallium may improve the electron mobility of semiconductor materials, achieving lower operating voltage and lower power consumption compared to traditional semiconductor materials such as silicon, etc. The introduction of zinc helps to improve the stability of semiconductor materials. IGZO materials may directly couple the semiconductor body 1101 with metal materials of the bit line 131, the capacitor structure 120, or other contact structures 160, thereby reducing contact resistance.

The electrodes in the gate layer 1103 and the capacitor structure 120 may include, but are not limited to, conductive materials such as tungsten, gold, silver, platinum, copper, aluminum, titanium, cobalt, or nickel, etc. In addition to the conductive materials mentioned above, the bit line 131 may also include doped semiconductor materials, such as doped silicon, etc., or may include metal silicides.

The gate dielectric layer 1102 and the isolation material 141 may include but are not limited to insulating materials such as silicon oxide, silicon nitride, silicon oxynitride, or aluminum oxide, etc. The gate dielectric layer 1102 may be the same or similar to the isolation material 141 filled between adjacent semiconductor bodies 1101, and may not have a clear physical boundary. In FIG. 4, the dielectric materials of the first dielectric layer 101 in FIG. 2 and the capacitor structure 120 are the same without any physical boundary therebetween.

The first capacitor structure 121 in FIG. 4 may have the same or different device structure as the second capacitor structure 122, the first contact structure 161 coupled to the first capacitor structure 121 may be the same as the second contact structure 162, and the first transistor 111 coupled to the first contact structure 161 may have the same structure as the second transistor 112, which will not be repeated here. For example, the first transistor 111 may include a first semiconductor body 1111 extending along the z-direction, a conductive layer 1131 covering sidewalls between the first and second ends of the first semiconductor body 1111, and a first dielectric layer 1121 located between the conductive layer 1131 and the first semiconductor body 1111. The bit line 131 in FIG. 4 is broken or passed through, and different bit lines 131 coupled to the first transistor 111 and the second transistor 112 respectively may be selected respectively. For example, the first transistor 111 may be coupled to the peripheral circuit 210 through the first bit line 131a, the connection structure 155, and the bonding contact 133, and the second transistor 112 may be coupled to the peripheral circuit 210 through the second bit line 131b, the connection structure 153, and the bonding contact 133.

In some implementations, as shown in FIG. 4, the interconnect layer 134 coupled to the second capacitor structure 122 in FIG. 3 may be broken and coupled to the second capacitor structure 122 and the first capacitor structure 121, respectively, or different interconnects in the interconnect layer 134 may be coupled to the second capacitor structure 122 and the first capacitor structure 121, respectively. For example, the interconnect 134a is coupled to the first capacitor structure 121, the interconnect 134b is coupled to the second capacitor structure 122, and then the interconnect 134a and the interconnect 134b are coupled to the peripheral circuit 210 through different connection structures. In some other implementations, the first capacitor structure 121 and the second capacitor structure 122 may share the same common voltage terminal, for example, may be coupled through the same interconnect layer 134 or interconnect lines connected to the same common voltage terminal, and connected to the common voltage terminal of the peripheral circuit 210 through the same connection structure 152. For example, the first capacitor structure 121 in FIG. 4 is used as a decoupling capacitor. A turn-on voltage is applied to the conductive layer 1131 to turn on the first transistor 111, to select at least one first capacitor structure 121 that needs to be connected to the circuit. At this time, the voltage of the first bit line 131a may be input to the first capacitor structure 121 via the first transistor 111, or the voltage of the first capacitor structure 121 may be output to the first bit line 131a via the first transistor 111.

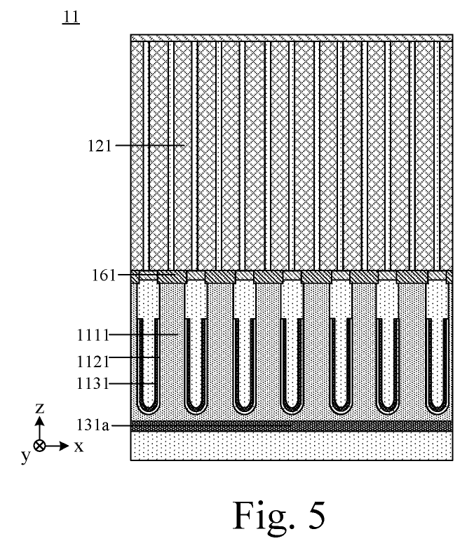

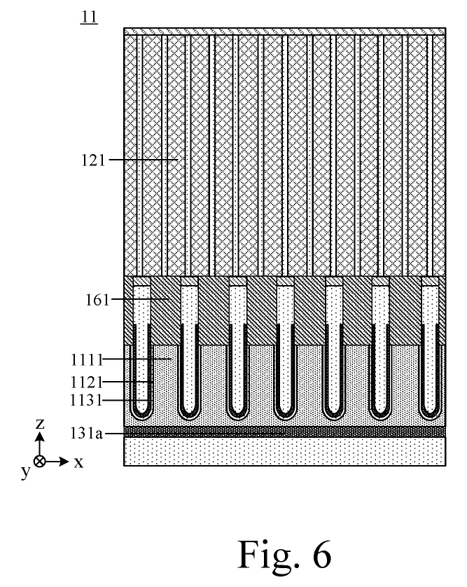

In some implementations, the first capacitor structure 121 serving as a decoupling capacitor may not be selected separately, instead, one conductive layer 1131 may be selected while a plurality of first capacitor structures 121 in series or parallel are selected simultaneously. Referring to the first semiconductor structure 11 shown in FIG. 5 and FIG. 6, the shape of the cross-section of the conductive layer 1131 between two adjacent first semiconductor bodies 1111 in the xoz plane is U-shaped or approximately U-shaped. One U-shaped conductive layer 1131 may correspond to or enable two first semiconductor bodies 1111, so that two first capacitor structures 121 may be selected and connected to the circuit. The two first capacitor structures 121 may be connected in series or parallel. The first contact structure 161 in FIG. 5 is located on the first semiconductor body 1111 and is not in contact with the conductive layer 1131. The selection or power supply of the first capacitor structure 121 requires the turn-on of the first semiconductor body 1111.

In some implementations, the whole of the first semiconductor body 1111 in FIG. 5 may be doped with the same type, so that the first semiconductor body 1111 is a conductor, the conductive layer 1131 does not control the turn-on of the first semiconductor body 1111, and the conductive layer 1131 and the first semiconductor body 1111 will not constitute a transistor structure. At this time, the conductive layer 1131 may be grounded to reduce crosstalk between the first semiconductor bodies 1111, or the conductive layer 1131 may be removed. In some other implementations, as shown in FIG. 6, the first contact structure 161 may be in direct contact with the conductive layer 1131 to provide power to the first capacitor structure 121 or form an electrical signal interconnection.

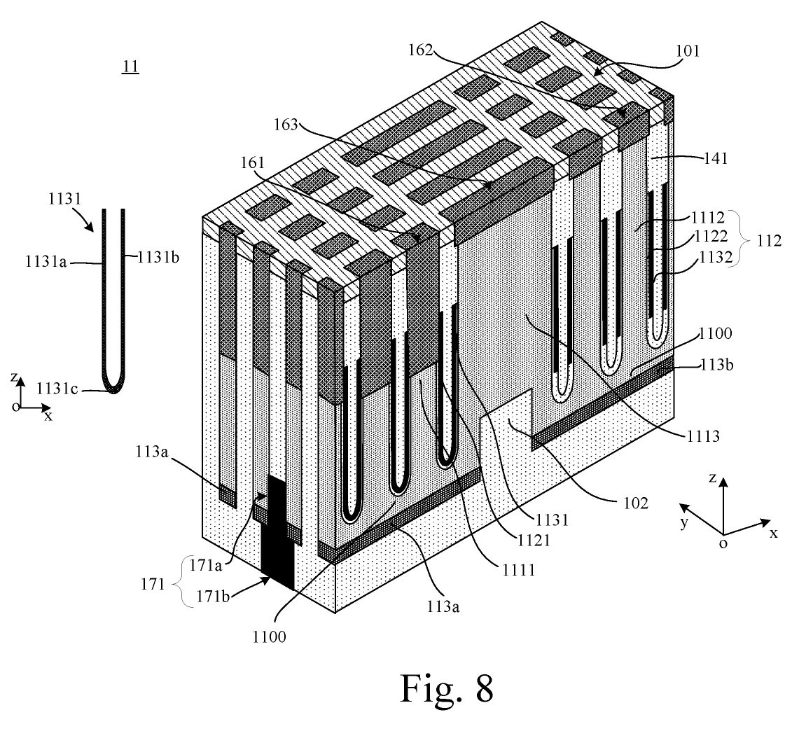

In some implementations, the conductive layer 1131 and the gate layer 1132 may be manufactured using the same manufacturing process, such as applying the same photolithography mask. Retaining the conductive layer 1131 may reduce adjustments to the manufacturing process and redesign of the photolithography mask, which is beneficial for reducing manufacture costs and process integration. Referring to FIG. 6, the height of the first semiconductor body 1111 may be reduced, and the first contact structure 161 extends towards the first semiconductor body 1111 between adjacent ones of the conductive layers 1131. The conductive layer 1131 overlaps at least partially with the first contact structure 161 in the x-direction, and the conductive layer 1131 may be in direct contact with and connect to the first contact structure 161. In the x-direction, the first dielectric layer 1121 at the overlapping area between the conductive layer 1131 and the first contact structure 161 is removed, so that the conductive layer 1131 is in direct contact with and connect to a sidewall of the first contact structure 161, or the first dielectric layer 1121 may be removed completely. In some implementations, a connection structure may be disposed to couple with the conductive layer 1131 to enable electrical lead-out of the conductive layer 1131, such as a first connection structure 171 illustrated with reference to FIG. 8 below. Compared to the use of the first semiconductor body 1111 and the first bit line 131a to electrically lead out the first capacitor structure 121, the use of the conductive layer 1131 with a lower resistance to electrically lead out the first capacitor structure 121 is beneficial for reducing resistance, e.g., beneficial for forming the all-metal electrical lead-out of the first capacitor structure 121, the first contact structure 161, and the conductive layer 1131 to reduce resistance.

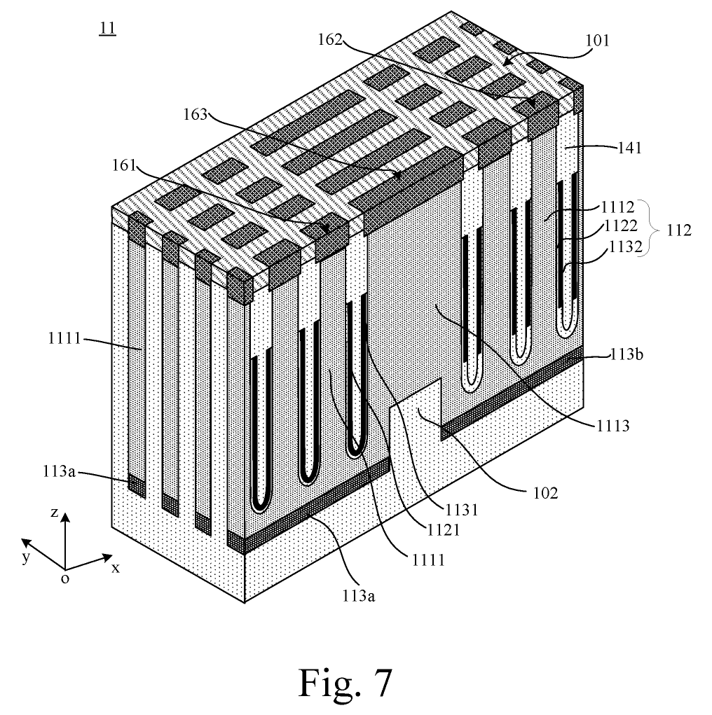

In some implementations, FIG. 7 illustrates an example of structure of the conductive layer 1131 and the gate layer 1132. The shape of the cross-section of the conductive layer 1131 in the xoz plane is U-shaped or approximately U-shaped, and the shape of the cross-section of the gate layer 1132 in the xoz plane is strip-shaped. In the x-direction, a third semiconductor body 1113 may be disposed between adjacent first and second semiconductor bodies 1111 and 1112, or the third semiconductor body 1113 may be located at the junction of the first and second semiconductor bodies 1111 and 1112. The bit line 131 located in the third semiconductor body 1113 is removed to broke the bit line 131, thus forming a first bit line 131a corresponding to the first semiconductor body 1111 and a second bit line 131b corresponding to the second semiconductor body 1112. Alternatively, a first isolation structure 102 may be disposed on a side of the third semiconductor body 1113 close to the bit line 131, and the first isolation structure 102 may extend into the third semiconductor body 1113 along the z-direction to cut off the bit line 131. A third contact structure 163 may or may not be disposed on the third semiconductor body 1113. The third contact structure 163 is a dummy contact structure and does not need to be coupled to the device structure.

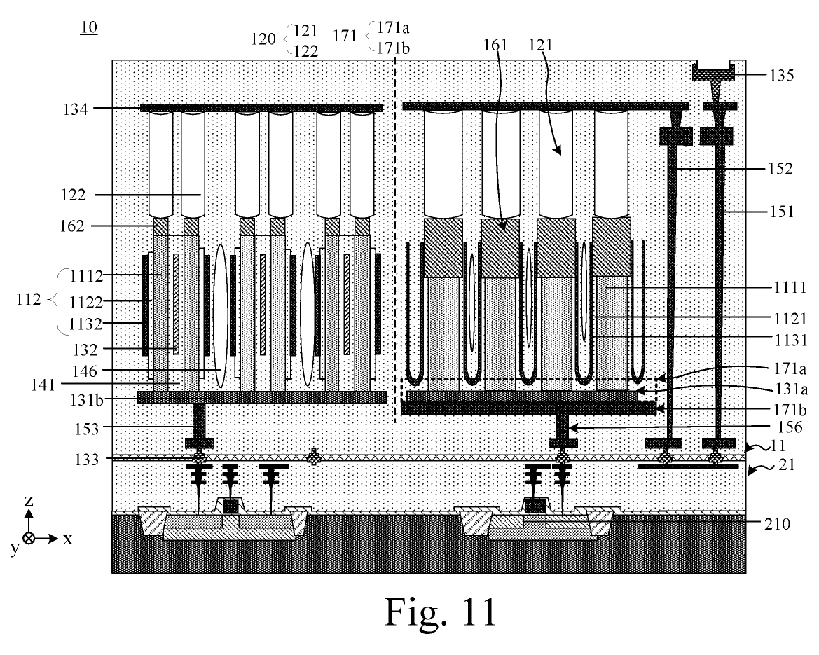

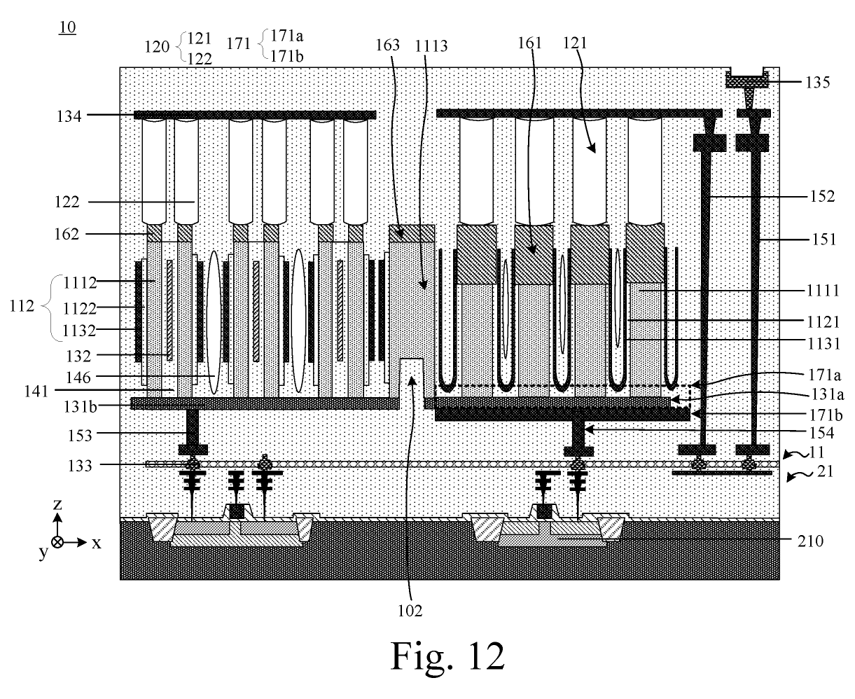

In some implementations, as shown in FIG. 7, the sizes of the first semiconductor body 1111 and the second semiconductor body 1112 in the x-direction may be equal or substantially equal within a certain error range. One second semiconductor body 1112 may correspond to two gate layers 1132. In some implementations, the second contact structure 162 and the second semiconductor body 1112 may be etched along the z-direction, and the second semiconductor body 1112 is divided into smaller sized semiconductor bodies such that one gate layer 1132 corresponds to one semiconductor body 1101, as illustrated in FIGS. 11 and 12 below. At this time, the size of the remaining second semiconductor body 1112 in the x-direction may be smaller than that of the first semiconductor body 1111 in the x-direction.

In some implementations, as shown in FIG. 7, the sizes of the first semiconductor body 1111 and the second semiconductor body 1112 in the z-direction are equal or substantially equal, and the top surfaces of the first semiconductor body 1111, the second semiconductor body 1112, and the third semiconductor body 1113 are flush or substantially flush. The sizes of the first contact structure 161 and the second contact structure 162 in the z-direction may be equal or substantially equal within a certain error range.

According to some aspects of implementations of the present disclosure, FIG. 8 provides a semiconductor device 10 comprising a first semiconductor structure 11. The first semiconductor structure 11 comprises:

first semiconductor bodies 1111 extending along a first direction (z-direction), wherein the first semiconductor body 1111 has a first end and a second end arranged opposite to each other along the z-direction; conductive layers 1131 extending along a second direction (y-direction), wherein the conductive layer 1131 is located between the first semiconductor bodies 1111 that are adjacent in a third direction (x-direction), the y-direction intersects with the x-direction, and a plane formed by the y-direction and x-direction (such as an xoy plane) intersects or is perpendicular to the z-direction; a first contact structure 161 located on a side close to the first end of the first semiconductor body 1111 in the z-direction, wherein an end of the first contact structure 161 close to the first semiconductor body 1111 is located between adjacent ones of the conductive layers 1131, a sidewall of the first contact structure 161 extending along the z-direction overlaps at least partially with the conductive layer 1131 in the x-direction, and is connected to the conductive layer 1131.

In FIG. 8, the first end and second end of the first semiconductor body 1111 are the top and bottom, respectively, and the first end may be an end away from the bit line 131 (or the first bit line 131a). The first semiconductor body 1111 and the conductive layer 1131 may not constitute a transistor structure, and the first semiconductor body 1111 may not be doped. First and second ends of a second semiconductor body 1112 are doped, and the second semiconductor body 1112 and the gate layer 1132 constitute a transistor structure such as a second transistor 112. The second end of the second semiconductor body 1112 is coupled to the second bit line 131b. The first bit line 131a located on a side of the second end of the first semiconductor body 1111 may be removed, or the bit line 131 in this portion is not provided with the contact structure 160 for electrically leading out.

The first contact structure 161 extends towards the first semiconductor body 1111 between adjacent ones of the conductive layers 1131, and the conductive layer 1131 overlaps at least partially with the first contact structure 161 in the x-direction. The conductive layer 1131 may be in direct contact with and connect to the first contact structure 161. In the x-direction, the first dielectric layer 1121 at the overlapping area between the conductive layer 1131 and the first contact structure 161 is removed, so that the conductive layer 1131 is in direct contact with and connect to a sidewall of the first contact structure 161, or the first dielectric layer 1121 may be removed completely.

In some implementations, the first contact structure 161 may include a single-layer structure or a multi-layer structure, and the first contact structure 161 may include a metal silicide to increase adhesion between the first semiconductor body 1111 and the first semiconductor body 1111, such as titanium silicide. The first contact structure 161 may include a multi-layer structure, in which the portion close to the first semiconductor body 1111 and the portion in contact with the first semiconductor body 1111 may include a metal silicide to improve adhesion, and the portion for connecting and contacting the second capacitor structure 122 may include a metal to improve electrical connection performance. The first contact structure 161 in FIG. 8 is not electrically interconnected with the first semiconductor body 1111. Both the first contact structure 161 and the conductive layer 1131 may be made of metal materials to achieve all metal interconnection and reduce resistance. For example, the second contact structure 162 is electrically interconnected with the second semiconductor body 1112, and materials of the second contact structure 162 and the first contact structure 161 may be different. For example, the second contact structure 162 may include a metal silicide, such as tungsten silicide or titanium silicide, to reduce the contact resistance between the second contact structure 162 and the second semiconductor body 1112. For example, composition materials of the first contact structure 161 and the conductive layer 1131 may include, but are not limited to, conductive materials such as tungsten, gold, silver, platinum, copper, aluminum, titanium, cobalt, or nickel, etc. The size of the first contact structure 161 in the z-direction is larger than that of the second contact structure 162.

In some implementations, as shown in FIG. 8, the semiconductor device 10 (or the first semiconductor structure 11) further comprises: a first dielectric layer 1121 located between the first semiconductor body 1111 and the conductive layer 1131, in which an end of the conductive layer 1131 close to the first contact structure 161 protrudes from the first dielectric layer 1121 in the z-direction towards the first contact structure 161.

In FIG. 8, a portion of sidewalls of the first contact structure 161 overlaps with a portion of the conductive layer 1131, and there is no first dielectric layer 1121 at the overlapping area between the conductive layer 1131 and the first contact structure 161. The top surface of the conductive layer 1131 is higher than that of the conductive layer 1131. The top surface of the conductive layer 1131 may be flush or substantially flush with the top surface of the gate layer 1132, or the top surface of the conductive layer 1131 is higher than that of the gate layer 1132, so as to facilitate contact with the first contact structure 161 and reduce the extension distance of the first contact structure 161 in the z-direction, thereby reducing resistance. The bottom of the conductive layer 1131 may be lower than that of the gate layer 1132 to facilitate the contact between the first connection structure 171 and the conductive layer 1131 in FIG. 8, reduce the extension distance or lead distance of the first connection structure 171 in the z-direction, thereby reducing resistance. The size of the conductive layer 1131 in the z-direction is larger than that of the gate layer 1132.

In some implementations, the size of the first contact structure 161 extending downward may be increased, or the size of the conductive layer 1131 in the z-direction may be reduced, so that the entire area of the conductive layer 1131 is in contact with and connected to the sidewalls of the first contact structure 161. At this time, the first dielectric layer 1121 may not be disposed.

In some implementations, as shown in FIG. 8, the first contact structure 161 covers the first dielectric layer 1121 in the z-direction. The surface of the first dielectric layer 1121 close to the first contact structure 161 in the z-direction is flush with the surface of the first end of the first semiconductor body 1111. The first contact structure 161 is located above the first dielectric layer 1121, and the size of the first contact structure 161 in the x-direction may be larger than the size of the first semiconductor body 1111 in the x-direction. The top surface of the first dielectric layer 1121 may be flush or not flush with the top surface of the first semiconductor body 1111.

In some implementations, the top surface of the first dielectric layer 1121 may be lower than that of the first semiconductor body 1111, and a portion of the first contact structure 161 extends downwards towards the first dielectric layer 1121, extending between the conductive layer 1131 and the first semiconductor body 1111. In some other implementations, the top surface of the first dielectric layer 1121 may be higher than that of the first semiconductor body 1111, but lower than that of the conductive layer 1131. The first contact structure 161 covers the top surface of the first dielectric layer 1121 and extends downwards, so that the first contact structure 161 also covers a side surface of the first dielectric layer 1121 until it reaches the top surface of the first semiconductor body 1111. The wider range of configuration of topography of the first dielectric layer 1121 facilitates to expand the manufacturing process window.

In some implementations, as shown in FIG. 8, the z-direction and x-direction form a first plane (such as the xoz plane), and the cross-sectional figure of the conductive layer 1131 in the first plane includes: a first portion 1131a and a second portion 1131b extending along the z-direction, which are disposed at intervals in the x-direction; and a third portion 1131c located between the first portion 1131a and the second portion 1131b in the x-direction, wherein the third portion 1131c is located at an end of the first portion 1131a and the second portion 1131b away from the first contact structure 161, and connects the first portion 1131a and the second portion 1131b.

FIG. 8 also shows an enlarged schematic diagram of the conductive layer 1131. The shape of the cross-section of the conductive layer 1131 located between two adjacent first semiconductor bodies 1111 in the xoz plane is U-shaped or approximately U-shaped. The first portion 1131a and the second portion 1131b of the conductive layer 1131 are side surfaces of the conductive layer 1131 extending along the z-direction, covering sidewalls of the two adjacent first semiconductor bodies 1111, respectively. The third portion 1131c is located at the bottom of the conductive layer 1131 and connects the first portion 1131a and the second portion 1131b. The third portion 1131c may be a straight line extending along the x-direction, or an arc shape protruding towards or away from the first contact structure 161, or other irregular shapes with protrusions or bulges. Composition materials of the first portion, second portion 1131b, and third portion 1131c of the conductive layer 1131 may be the same, and the three portions form a whole.

In some implementations, as shown in FIG. 8, the third portion 1131c includes an arc shape, protrudes from the first portion 1131a and the second portion 1131b along the z-direction, and protrudes away from the first contact structure 161 along the z-direction.

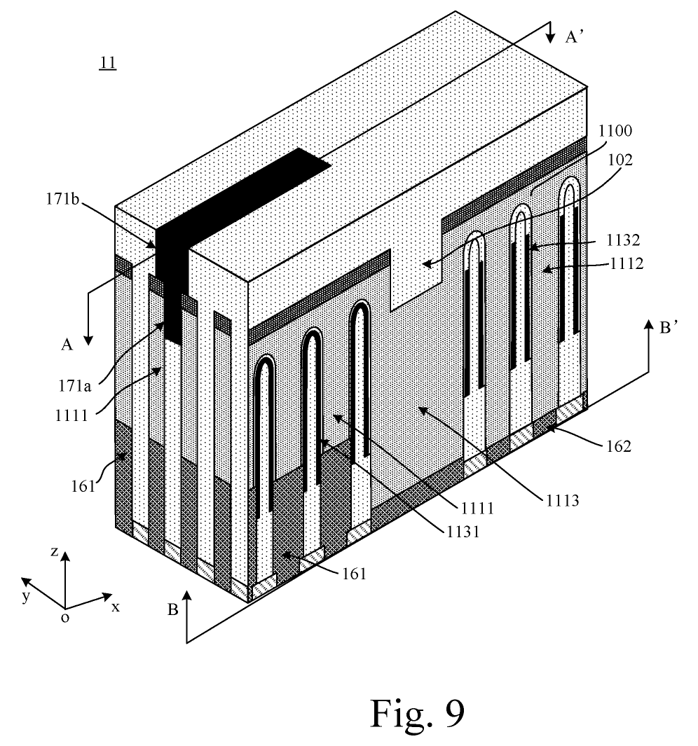

In some implementations, referring to FIGS. 8 and 9, the semiconductor device 10 (or the first semiconductor structure 11) further comprises: a first connection structure 171 extending along the x-direction and located on a side of the conductive layer 1131 away from the first contact structure 161. At least a portion of the first connection structure 171 is located between two first semiconductor bodies 1111 that are adjacent in the y-direction. The first connection structure 171 is connected to the conductive layer 1131.

The semiconductor structure shown in FIG. 9 is obtained by flipping the semiconductor structure in FIG. 8 upside down. As shown in FIG. 9, the first connection structure 171 is located on a side of the first semiconductor body 1111 away from the first contact structure 161, and is connected to a side of the conductive layer 1131 away from the first contact structure 161 for leading out. The first connection structure 171 extends in the region between the first semiconductor bodies 1111 that are adjacent in the y-direction, and the first connection structure 171 extends as a whole along the x-direction to connect the ends of a plurality of the conductive layers 1131 away from the first contact structure 161. The first connection structure 171 does not extend to the region where the gate layer 1132 is located, e.g., in FIG. 9, may extend on a side of the first isolation structure 102 away from the second bit line 131b in the x-direction, or the first connection structure 171 may extend into the first isolation structure 102 but not penetrate the first isolation structure 102 along the x-direction. A portion of the first connection structure 171 extends along the z-direction between two first semiconductor bodies 1111 that are adjacent in the y-direction and overlaps with the first semiconductor body 1111 in the y-direction, while another portion is located on a side of the first semiconductor body 1111 away from the first contact structure 161.

In some implementations, as shown in FIG. 9, the first connection structure 171 includes: a first portion 171a and a second portion 171b that are connected, in which the first portion 171a is located between two first semiconductor bodies 1111 that are adjacent in the y-direction, and the first portion 171a of the first connection structure 171 partially overlaps with the first semiconductor body 1111 in the y-direction; the second portion 171b of the first connection structure 171 is located on a side of the second end of the first semiconductor body 1111 away from the first contact structure 161, and the size of the second portion 171b in the y-direction is larger than the size of the first portion 171a in the y-direction. The size of one end of the first connection structure 171 away from the first contact structure 161 in the y-direction may be larger than the size of one end of the first connection structure 171 close to the first contact structure 161 in the y-direction, so that the cross-sectional figure of the first connection structure 171 on the yoz plane may be T-shaped or nearly T-shaped. The second portion 171b provides a portion having a larger size in the y-direction, while the first portion 171a provides a portion having a smaller size in the y-direction. The second portion 171b of a larger size facilitates to provide a larger landing area for the lead-out power supply structure of the first connection structure 171, so as to reduce the contact resistance and expand the process window. The second portion 171b of a larger size also provides a greater anchoring force, reducing void defects between the second portion 171b and the dielectric material.

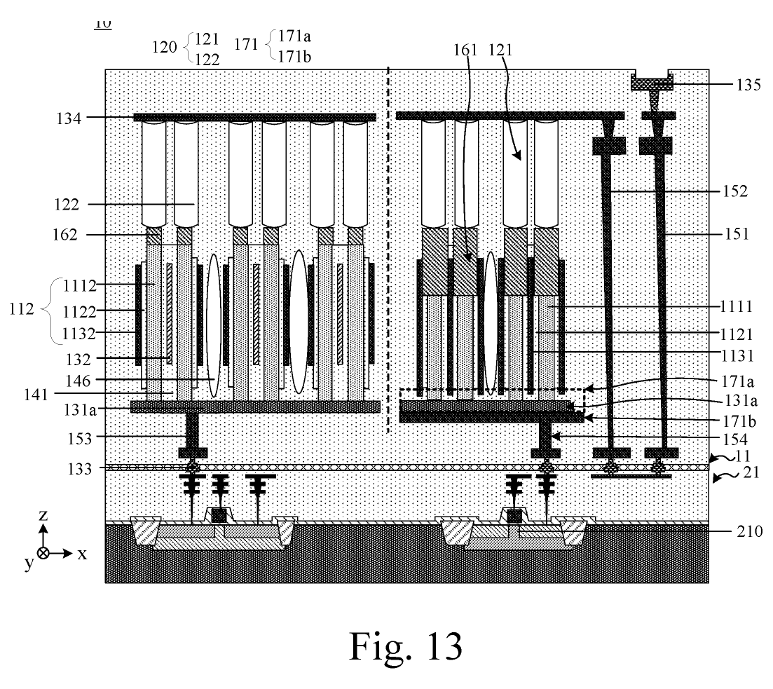

In some implementations, the conductive layer 1131 may be a strip-shaped structure similar to that of the gate layer 1132, as illustrated in FIG. 13 below. The first connection structure 171 may be connected to a plurality of strip-shaped conductive layers 1131. In some implementations, the first portion 171a of the first connection structure 171 may stop at one end of the conductive layer 1131 away from the first contact structure 161. Alternatively, the first portion 171a of the first connection structure 171 may continue to extend towards the first contact structure 161, covering the sidewall of the conductive layer 1131, such as covering the sidewall of the strip-shaped conductive layer 1131, covering an arc-shaped third portion 1131c of a U-shaped conductive layer 1131, or covering a sidewall of a strip-shaped first portion 1131a of the U-shaped conductive layer 1131. Alternatively, an end of the conductive layer 1131 away from the first contact structure 161 extends into the first portion 171a of the first connection structure 171.

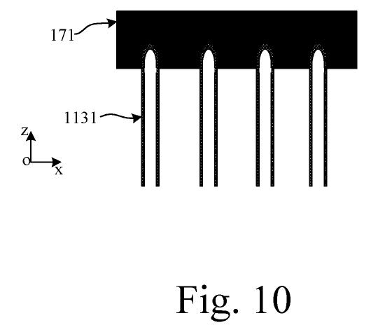

In some implementations, a portion of the first connection structure 171 connects the sidewalls of the conductive layer 1131 extending along the z-direction, and covers the sidewalls of the conductive layer 1131 extending along the z-direction to form a connection. FIG. 10 illustrates a partial cross-sectional view in the xoz plane taken along the line AA' in FIG. 9. The conductive layer 1131 extends into the first portion 171a of the first connection structure 171 along the z-direction, e.g., the U-shaped third portion 1131c of the conductive layer 1131 extends into the first portion 171a of the first connection structure 171. Alternatively, the conductive layer 1131 continues to extend along the first connection structure 171, so that a portion of the strip-shaped first portion 1131a of the conductive layer 1131 extends into the first connection structure 171 and is covered by the first connection structure 171.

In some implementations, as shown in FIGS. 8 and 9, the semiconductor device 10 (or the first semiconductor structure 11) further comprises: a second semiconductor body 1112 extending along a z-direction, wherein the second semiconductor body 1112 has a first end and a second end arranged opposite to each other along the z-direction; a second contact structure 162 located on a side close to a first end of the second semiconductor body 1112 in the z-direction, wherein the second contact structure 162 is connected to the first end of the second semiconductor body 1112, the size of the second semiconductor body 1112 in the z-direction is larger than that of the first semiconductor body 1111 in the z-direction, the size of the second contact structure 162 in the z-direction is smaller than that of the first contact structure 161 in the z-direction, and the first end of the second semiconductor body 1112 partially overlaps with the first contact structure 161 in the x-direction. In FIG. 8, the top surface of the first semiconductor body 1111 is lower than that of the second semiconductor body 1112, and the bottom surface of the first contact structure 161 is lower than that of the second contact structure 162. The first contact structure 161 extends between adjacent conductive layers 1131.

In some implementations, as shown in FIGS. 8 and 9, the semiconductor device 10 (or the first semiconductor structure 11) further comprises: a gate layer 1132 extending along the y-direction, wherein the gate layer 1132 is located between second semiconductor bodies 1112 that are adjacent in the x-direction, on a side of the second semiconductor body 1112 in the x-direction, and may cover sidewalls extending along the z-direction between the first and second ends of the second semiconductor body 1112; a second dielectric layer 1122 located between the second semiconductor body 1112 and the gate layer 1132, wherein the size of the second dielectric layer 1122 in the z-direction is larger than that of the first dielectric layer 1121 in the z-direction; and a bit line 131 extending along the x-direction, wherein at least a portion of the bit line 131 is connected to the second end of the second semiconductor body 1112, and at least a portion of bit line 131 is electrically connected or interconnected with the second semiconductor body 1112.

In some implementations, as shown in FIGS. 8 and 9, there are two gate layers 1132 between two adjacent second semiconductor bodies 1112 in the x-direction, and the two gate layers 1132 are electrically isolated from each other. In some implementations, composition materials of the gate layer 1132 and the conductive layer 1131 are the same. Unlike the U-shaped conductive layer 1131, the gate layer 1132 is strip-shaped. After removing or breaking the U-shaped third portion 1131c of the conductive layer 1131, two gate layers 1132 in face-to-face configuration may be obtained.

In FIG. 8, for ease of manufacture, the top surface of the conductive layer 1131 and the top surface of the gate layer 1132 may be at the same height or substantially flush. A portion of sidewalls of the first contact structure 161 overlaps with a portion of the conductive layer 1131, and there is no first dielectric layer 1121 in the overlapping area between the conductive layer 1131 and the first contact structure 161, so that the conductive layer 1131 is in contact with and connected to the sidewall of the first contact structure 161, which reduces the height of the top surface of the first dielectric layer 1121, making the size of the first dielectric layer 1121 in the z-direction smaller than that of the second dielectric layer 1122 in the z-direction. Since the conductive layer 1131 and the first semiconductor body 1111 do not constitute a transistor structure, the first dielectric layer 1121 may not be disposed between the first semiconductor body 1111 and the conductive layer 1131.

The first contact structure 161 uses the conductive layer 1131 to lead out, instead of using the bit line 131 and the semiconductor body 1101, such that the bit line 131 may not be disposed on a side of the first semiconductor body 1111 away from the first contact structure 161. As shown in FIGS. 8 and 9, in order to reduce the manufacturing process, a continuous bit line 131 is disposed on a side of the first semiconductor body 1111 and the second semiconductor body 1112 away from the contact structure 160, and a first isolation structure 102 extending in the y-direction is disposed at the junction of the first semiconductor body 1111 and the second semiconductor body 1112 to break the bit line 131, thus forming a first bit line 131a corresponding to the first semiconductor body 1111 and a second bit line 131b corresponding to and electrically connected to the second semiconductor body 1112, in which the first bit line 131a is not electrically interconnected with the first semiconductor body 1111, and the first bit line 131a may not be provided with a connection structure for leading out. In some implementations, the first bit line 131a may be removed, leaving only the second bit line 131b.

In some implementations, as shown in FIGS. 8 and 9, the semiconductor device 10 (or the first semiconductor structure 11) further comprises: a third semiconductor body 1113 located between the first semiconductor body 1111 and the second semiconductor body 1112 in the x-direction, in which the bit line 131 includes a first bit line 131a and a second bit line 131b, the first bit line 131a corresponds to a second end of the first semiconductor body 1111, and the second bit line 131b is connected to the second end of the second semiconductor body 1112, and the first bit line 131a may be physically but not electrically connected to the second end of the first semiconductor body 1111, that is, the first bit line 131a is not used for power supply or lead out for the first semiconductor body 1111;

a first isolation structure 102 extending along the y-direction, in which the first isolation structure 102 is located at an end of the third semiconductor body 1113 away from the first contact structure 161 in the z-direction, located between the first bit line 131a and the second bit line 131b, and isolates the first bit line 131a and the second bit line 131b. The first isolation structure 102 penetrates through the bit line 131 along the z-direction and extends into the third semiconductor body 1113 to divide the bit line 131 into the first bit line 131a and the second bit line 131b. The third semiconductor body 1113 is also shown in FIG. 12 below.

In the x-direction, the third semiconductor body 1113 is disposed between the first semiconductor body 1111 and the second semiconductor body 1112 that are adjacent, or the third semiconductor body 1113 is located at the junction of the first semiconductor body 1111 and the second semiconductor body 1112. A portion of the bit line 131 located in the third semiconductor body 1113 is removed to break the bit line 131, and form the first bit line 131a corresponding to the first semiconductor body 1111 and the second bit line 131b corresponding to the second semiconductor body 1112. Alternatively, the first isolation structure 102 may be disposed on a side of the third semiconductor body 1113 close to the bit line 131, and may extend into the third semiconductor body 1113 along the z-direction to cut off the bit line 131. A third contact structure 163 may or may not be disposed on the third semiconductor body 1113. The third contact structure 163 is a dummy contact structure and is not configured for coupling device structures. The size of the third semiconductor body 1113 along the x-direction may be larger than that of the first semiconductor body 1111 and larger than that of the second semiconductor body 1112, to reduce leakage between two portions of the semiconductor body 1101. The third semiconductor body 1113 may be doped or not doped.

In some implementations, as shown in FIGS. 8 and 9, the first isolation structure 102 has a first side and a second side arranged opposite to each other in the x-direction, and the semiconductor device 10 further comprises: a plurality of first semiconductor bodies 1111 arranged along the x-direction, wherein second ends of the plurality of first semiconductor bodies 1111 are connected to each other and located on a first side of the first isolation structure 102 (left side of FIG. 8); a plurality of second semiconductor bodies 1112 arranged along the x-direction, wherein second ends of the plurality of second semiconductor bodies 1112 are connected to each other and located on a second side of the first isolation structure 102 (right side of FIG. 8). In some implementations, as shown in FIGS. 8 and 9, the semiconductor device 10 (or the first semiconductor structure 11) further comprises: a semiconductor strip 1100 extending along the x-direction, wherein the semiconductor strip 1100 is located between the bit line 131 and the first semiconductor body 1111, between the second semiconductor body 1112 and the third semiconductor body 1113, and the bit line 131 is connected to the semiconductor strip 1100. The semiconductor strip 1100 connects the second end of the first semiconductor body 1111, the second end of the second semiconductor body 1112, and the second end of the third semiconductor body 1113. The first isolation structure 102 also penetrates through the semiconductor strip 1100.

First ends of the plurality of semiconductor bodies 1101 are connected by a semiconductor material or the semiconductor strip 1100. The semiconductor strip 1100 is a residual and unbroken portion leaved when etching a semiconductor layer to form the plurality of semiconductor bodies 1101. The semiconductor strip 1100 extends along the x-direction, and there is no obvious physical boundary between the semiconductor strip 1100 and the plurality of semiconductor bodies 1101. A side of the semiconductor strip 1100 away from the semiconductor body 1101 in the z-direction is used to form or carry the bit line 131. For example, in FIGS. 8 and 9, the bit line 131 may be formed based on performing heavy doping on the portion of the semiconductor strip 1100 region, or the bit line 131 may be formed based on performing metallization on the portion of the semiconductor region to form metal silicides, such as titanium silicide or tungsten silicide. The bit line 131 may not have a clear physical boundary with the first end of the semiconductor body 1101 or a portion of the semiconductor strip 1100. In some other implementations, a conductive material may be deposited on a side over the semiconductor strip 1100 and away from the semiconductor body 1101 to form the bit line 131, such as tungsten is deposited to form a metal bit line 131. The first isolation structure 102 penetrates through the bit line 131 at the third semiconductor body 1113 along the z-direction, and penetrates through the semiconductor strip 1100 at the third semiconductor body 1113 to extend into the third semiconductor body 1113, so as to reduce leakage between two portions of the semiconductor body 1101. The first isolation structure 102 at least partially overlaps with the conductive layer 1131 in the x-direction, and the first isolation structure 102 at least partially overlaps with the gate layer 1132 in the x-direction to reduce leakage and interference.

In some implementations, the first isolation structure 102 in FIG. 9 extends along the z-direction, penetrates through the third semiconductor body 1113, and penetrates through the third contact structure 163.

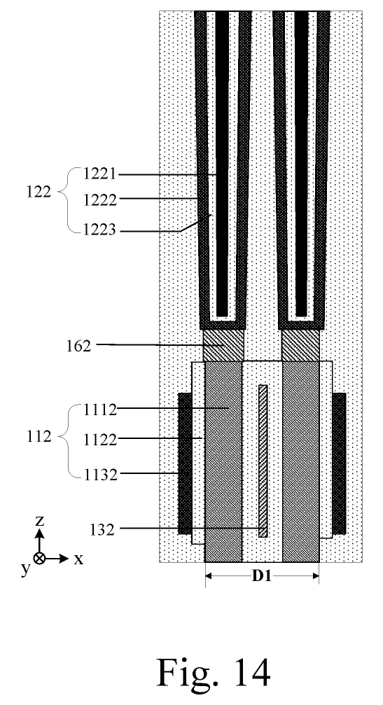

In some implementations, FIGS. 11, 12, and 13 illustrate diagrams of the peripheral circuit 210 and the capacitor structure 120 connected to respective contact structure 160, in which the semiconductor bodies, gate layers, and contact structures in FIG. 12 may correspond to the cross-sectional diagram taken along BB' in FIGS. 9, 12 also illustrates other devices not shown in FIGS. 9, and 14 illustrates a structural example of the second capacitor structure 122.

As shown in FIGS. 11 to 13, the semiconductor device 10 (or the second semiconductor structure 21) further comprises: a peripheral circuit 210 coupled to at least the conductive layer 1131, the gate layer 1132, and the bit line 131; a first capacitor structure 121 connected to the first contact structure 161, wherein the first capacitor structure 121 is at least configured as a decoupling capacitor in the peripheral circuit 210; and a second capacitor structure 122 connected to the second contact structure 162, wherein the second capacitor structure 122 is configured as a storage capacitor. The coupling between the first capacitor structure 121 and the second capacitor structure 122, and the peripheral circuit 210 may refer to FIG. 4, and will not be repeated here.

In some implementations, as shown in FIGS. 11 to 13, the first capacitor structure 121 is coupled to the peripheral circuit 210 through at least the first contact structure 161, the conductive layer 1131, and the first connection structure 171. In some implementations, the first capacitor structure 121 is configured as at least a decoupling capacitor in the peripheral circuit 210.

In FIGS. 11 to 13, a portion of the first connection structure 171 (such as 171a) is obscured due to the angle of the cross-sectional diagram, and the extended position of the first connection structure 171 is indicated by a dashed box in this figure. The first connection structure 171 may be coupled to the bonding contact 133 through the second connection structure 156 to achieve electrical interconnection between the first connection structure 171 and the peripheral circuit 210.

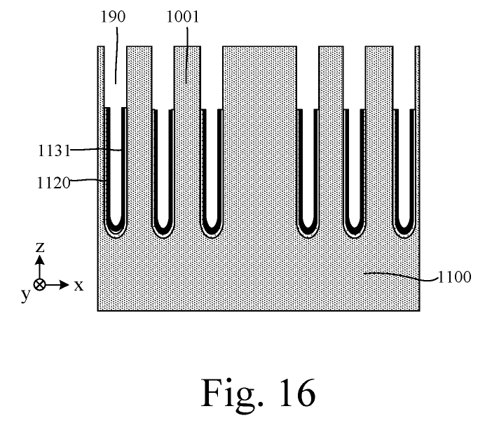

As shown in FIGS. 11 and 12, the size of the first semiconductor body 1111 in the x-direction is larger than that of the second semiconductor body 1112 in the x-direction. The second semiconductor body 1112 shown in FIGS. 11 and 12 is obtained by etching a semiconductor body with the same size as the first semiconductor body 1111, which may be considered as etching and dividing an initial semiconductor body (such as the initial semiconductor body 1001 in FIG. 16 below) into two second semiconductor bodies 1112 along the z-direction. The size of the initial semiconductor body in the x-direction is equal or substantially equal to that of the first semiconductor body 1111 in the x-direction. The initial semiconductor body is reduced in size in the z-direction to form the first semiconductor body 1111. As shown in FIG. 14, for two adjacent second semiconductor bodies 1112, two gate layers 1132 are arranged in back-to-back configuration on sidewalls of the two second semiconductor bodies 1112. The sum of a total size of the two second semiconductor bodies 1112 in the x-direction and a size of a gap therebetween is referred to as width D1, which is the size in the x-direction of the initial semiconductor body 1001 forming the two second semiconductor bodies 1112. The size of the first semiconductor body 1111 in the x-direction in FIGS. 11 and 12 is equal to or substantially equal to the width D1.

In some implementations, as shown in FIG. 13, the shape of the cross-section of the conductive layer 1131 in the xoz plane may be a strip extending along the z-direction, and the two first contact structures 161 are closely adjacent and connected by an intervening conductive layer 1131, that is, the left and right sides of the conductive layer 1131 are each connected to one first contact structure 161. In FIG. 13, the conductive layer 1131, the first contact structure 161, the conductive layer 1131, the first contact structure 161, and the conductive layer 1131 that are tightly arranged and connected in the x-direction are taken as a set of structures, in which three conductive layers 1131 are connected to two first contact structures 161, and multiple sets of structures are sequentially arranged in the x-direction to connect more first capacitor structures 121.

In some implementations, as shown in FIG. 13, the size of the first semiconductor body 1111 in the x-direction may be equal to that of the second semiconductor body 1112, and both the first semiconductor body 1111 and the second semiconductor body 1112 may be formed by etching and dividing the initial semiconductor body.

In some implementations, as shown in FIG. 14, a second transistor 112, a second contact structure 162 (or without the second contact structure 162), and a second capacitor structure 122 may constitute a memory cell, such as a DRAM memory cell. The second capacitor structure 122 may include a first electrode 1221 extending along the z-direction, a dielectric layer 1222 surrounding the first electrode 1221, and a second electrode 1223 surrounding the dielectric layer 1222. The dielectric layer 1222 is located between the first electrode 1221 and the second electrode 1223, and the second electrode 1223 is coupled to the first end of the second semiconductor body 1112 through the second contact structure 162. The size in the x-direction of an end of the second capacitor structure 122 away from the second semiconductor body 1112 in the z-direction may be larger than or equal to that of an end of the second capacitor structure 122 close to the second semiconductor body in the z-direction. The first electrodes 1221 of a plurality of second capacitor structures 122 may be coupled to an interconnect layer (such as the interconnect layer 134 in FIG. 2) for connecting to ground or other operating voltages. Alternatively, a plurality of capacitor structures 120 share the first electrode 1221, and an end of the first electrode 1221 away from the second semiconductor body 1112 has a film layer structure extending along the x-direction and/or y-direction. The first electrode 1221 is connected to ground or other operating voltages, and the plurality of second capacitor structures 122 share the first electrode 1221 and are connected to a common voltage. The example of the structure of the first capacitor structure 121 may refer to the second capacitor structure 122, which will not be repeated here. The plurality of first capacitor structures 121 are connected to the circuit by leading out from the gate layer 1132 and the first contact structure 161, and the connection may be in series or in parallel.

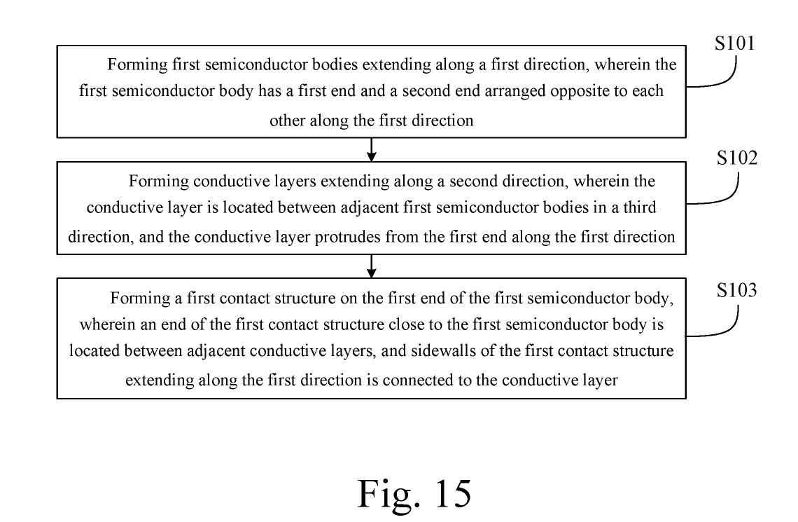

According to some aspects of implementations of the present disclosure, FIG. 15 provides a manufacturing method of a semiconductor device 10, including:

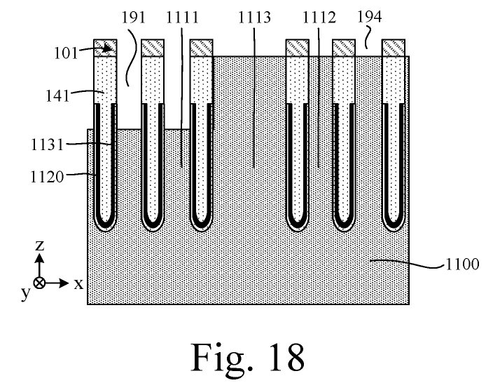

forming first semiconductor bodies 1111 as shown in FIG. 18 extending along a first direction (the z-direction), wherein the first semiconductor body 1111 has a first end and a second end arranged opposite to each other in the first direction;

as shown in FIG. 18, forming conductive layers 1131 extending along a second direction (the y-direction), wherein the conductive layer 1131 is located between the first semiconductor bodies 1111 that are adjacent in a third direction (the x-direction), and protrudes from the first end along the first direction, the second direction intersects with the third direction, and a plane formed by the second and third directions intersects with the first direction;

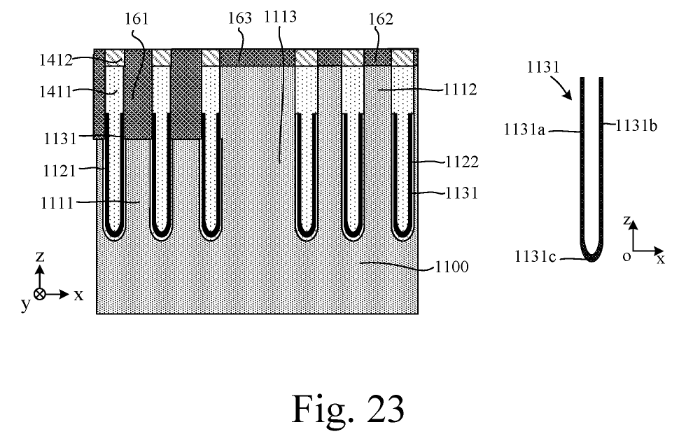

forming a first contact structure 161 as shown in FIG. 23 on the first end of the first semiconductor body 1111, wherein an end of the first contact structure 161 close to the first semiconductor body 1111 is located between adjacent ones of the conductive layers 1131, and a sidewall of the first contact structure 161 extending along the first direction is connected to the conductive layer 1131.

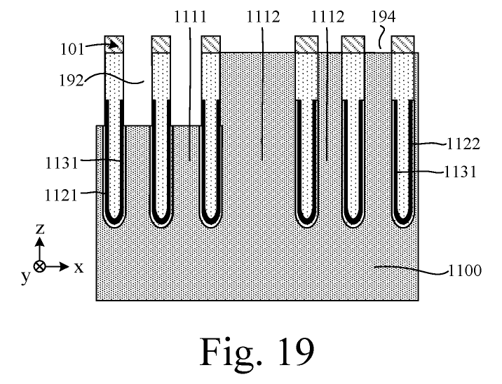

In some implementations, the manufacturing method further comprises: forming a first dielectric layer 1121 as shown in FIG. 19 between the first semiconductor body 1111 and the conductive layer 1131, wherein a top surface of the first dielectric layer 1121 in the z-direction is lower than that of the conductive layer 1131. Implementations of the present disclosure do not limit the manufacturing sequence of structures such as the first semiconductor body 1111, the first dielectric layer 1121, and the conductive layer 1131, etc.

In some implementations, the method for forming the conductive layer 1131 may include:

as shown in FIG. 16, providing a plurality of initial semiconductor bodies 1001 extending along the first direction (the z-direction), wherein the initial semiconductor body 1001 has a first end and a second end arranged opposite to each other in the first direction, and the plurality of initial semiconductor bodies 1001 include at least a second semiconductor body 1112;

as shown in FIG. 16, forming a dielectric layer 1120 and a conductive layer 1131 between adjacent initial semiconductor bodies 1001, wherein the dielectric layer 1120 is located between the initial semiconductor bodies 1001 and the conductive layer 1131, and the conductive layer 1131 extends along the y-direction and covers a portion of sidewalls of the initial semiconductor body 1001 extending along the z-direction. The conductive layer 1131 may expose, in the x-direction, the sidewalls of the first end of the initial semiconductor body 1001 extending along the z-direction.

In some implementations, as shown in FIG. 18, a portion of the plurality of initial semiconductor bodies 1001 are etched along the first direction to form the first semiconductor body 1111. The top surface of the first semiconductor body 1111 in the first direction is lower than that of the conductive layer 1131. The plurality of initial semiconductor bodies 1001 include at least the second semiconductor body 1112. The size of the second semiconductor body 1112 in the first direction is larger than that of the first semiconductor body 1111, and the top surface of the second semiconductor body 1112 is higher than that of the first semiconductor body 1111.

As shown in FIG. 19, the dielectric layer 1120 on the sidewalls of the first semiconductor body 1111 is etched to expose the conductive layer 1131 on the sidewalls of the first semiconductor body 1111 in the third direction (the x-direction). The etched dielectric layer 1120 forms the first dielectric layer 1121. The top surface of the first dielectric layer 1121 in the first direction is lower than that of the conductive layer 1131. A plane formed by the third and second directions intersects with the first direction.

As shown in FIG. 23, a first contact structure 161 is formed on the first end of the first semiconductor body 1111, with sidewalls of the first contact structure 161 extending along the first direction connected to the conductive layer 1131.

In some implementations, forming the first semiconductor structure 11 includes providing a semiconductor layer. The semiconductor layer is a semiconductor substrate or semiconductor wafer, or a semiconductor film layer formed by epitaxial deposition on the wafer, and the semiconductor layer may be backside thinned. The semiconductor layer is etched to form trenches extending along the x-direction and y-direction, dividing the semiconductor layer into the initial semiconductor bodies 1001. For example, the etching processes may include but are not limited to dry etching, wet etching, or any combination thereof.

In some implementations, the trench 190 extending along the y-direction is shown as an example in FIG. 16, while the trench extending along the x-direction is not shown since obscured in the cross-sectional diagram. The trench extending along the x-direction penetrates through the semiconductor layer, while the trench 190 extending along the y-direction does not completely penetrate the semiconductor layer. The remaining semiconductor material forms semiconductor strips 1100 extending along the x-direction and disposed at intervals. The initial semiconductor body 1001 is located on and connected to the semiconductor strip 1100, and there may be no obvious physical boundary between the initial semiconductor body 1001 and the semiconductor strip 1100. The initial semiconductor body 1001 and semiconductor strip 1100 may be illustrated as shown in FIG. 16.

In some implementations, the bit line 131 may be formed based on the semiconductor strip 1100. For example, the semiconductor strip 1100 is doped heavily to form the bit line 131, or the semiconductor strip 1100 is metalized to form a metal silicide to form the bit line 131, or a metal may be deposited on the metal silicide to form the bit line 131, or a metal may be deposited directly on the semiconductor strip 1100 to form the bit line 131.

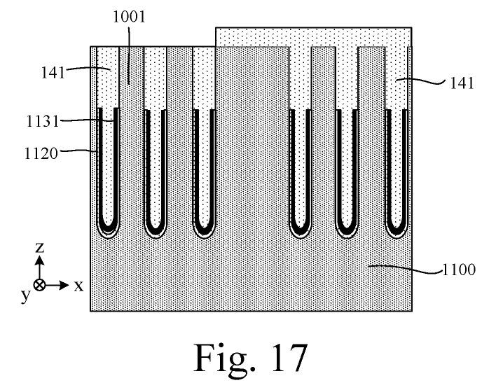

In some implementations, as shown in FIG. 16, a dielectric material is deposited on sidewalls of the trench 190 to form a dielectric layer 1120, and a conductive material is deposited on the dielectric layer 1120 on the sidewalls of the trench 190 to form an initial conductive layer, and a portion of the initial conductive layer located at an upper end of the trench 190 is removed to form the conductive layer 1131. In some implementations, a portion of the dielectric layer 1120 at the upper end of the trench 190 is removed, so that a top surface of the remaining of the dielectric layer 1120 is flush or substantially flush with a top surface of the conductive layer 1131. In FIG. 17, an isolation material 141 (or a dielectric material) is filled in the trench 190 and a trench extending along the x-direction that is not shown.

For example, deposition processes may include but are not limited to: Chemical Vapor Deposition (CVD), Physical Vapor Deposition (PVD), and Atomic Layer Deposition (ALD).

In some implementations, the manufacturing method further comprises: filling the isolation material 141 as shown in FIG. 17 between the adjacent initial semiconductor bodies 1001 with the conductive layer 1131, the isolation material 141 covering the dielectric layer 1120 and the conductive layer 1131. As shown in FIG. 18, the method for forming the first semiconductor body 1111 includes etching the isolation material 141 on a portion of the initial semiconductor body 1001 to expose the first end of the initial semiconductor body 1001.

In some implementations, as shown in FIG. 18, the method for forming the first semiconductor body 1111 includes: etching the portion of the initial semiconductor body 1001 exposed in FIG. 17 to form a plurality of first openings 191 arranged along the y-direction and x-direction, wherein the sidewalls at the bottom of the first opening 191 exposes a portion of the dielectric layer 1120 in the x-direction, the etched initial semiconductor body 1001 forms the first semiconductor body 1111, and the first opening 191 is located over the first end of the first semiconductor body 1111. The first opening 191 may be an opening, a groove, or a trench extending along the x-direction or y-direction. The shape of the first opening 191 may include a circle, an ellipse, a rectangle, or other regular, irregular polygons and arcs.

In an example, as shown in FIG. 17, a dielectric material or the isolation material 141 is filled in gaps between the initial semiconductor bodies 1001 that are adjacent in the x-direction and y-direction. The isolation material 141 covers the dielectric layer 1120 and the conductive layer 1131. The isolation material 141 may cover the top surface of the initial semiconductor body 1001. The isolation material 141 on a portion of the semiconductor body 1101 is etched and removed to expose the first end (the top end) of the initial semiconductor body 1001. The exposed initial semiconductor body 1001 is etched to reduce a height of the initial semiconductor body 1001 in the z-direction, to form the first opening 191 shown in FIG. 18. The remaining of the initial semiconductor body 1001 forms the first semiconductor body 1111, and the unetched initial semiconductor body 1001 may be used as the second semiconductor body 1112. The top surface of the second semiconductor body 1112 is higher than that of the first semiconductor body 1111. For example, the isolation material 141 may include but is not limited to dielectric materials such as silicon oxide, silicon nitride, silicon oxynitride, or aluminum oxide. Alternatively, the initial semiconductor body 1001 covered by the isolation material 141 in FIG. 17 serves as the second semiconductor body 1112.

The dielectric layer 1120 on the sidewalls of the first opening 191 is etched and removed to expose the conductive layer 1131. The etched dielectric layer 1120 forms a first dielectric layer 1121. The top surface of the first dielectric layer 1121 in the first direction is lower than that of the conductive layer 1131, and the top surface of the first dielectric layer 1121 may be flush with the top surface of the first semiconductor body 1111. The unetched dielectric layer 1120 may serve as a second dielectric layer 1122. A conductive material is filled in the first opening 191 in which a portion of the dielectric layer 1120 is removed and the conductive layer 1131 is exposed, to form a first contact structure 161. Sidewalls of the first contact structure 161 may be in contact with and connected to the conductive layer 1131.

In some implementations, the manufacturing method further includes: ion implanting, along the z-direction, the initial semiconductor body 1001 in which the first semiconductor body 1111 is to be formed in FIG. 17. In some implementations, the depth of ion implantation is lower than the top surface of the conductive layer 1131. In FIG. 17, using the isolation material 141 covering the initial semiconductor body 1001 as a doping mask, ion implantation is performed on the initial semiconductor body 1001 exposed by the isolation material 141 to accelerate the etching rate of the initial semiconductor body 1001 to facilitate the etching. The depth of ion implantation is lower than the top surface of the conductive layer 1131, so that the interface between the ion-implanted area and the non-ion-implanted area of the initial semiconductor body 1001 is located below the conductive layer 1131, in which the ion-implanted area may be removed quickly and the etching may be stopped at the non-ion-implanted portion of the semiconductor body, so that the top surface of the initial semiconductor body 1001 after the etching stops is located below the top surface of the conductive layer 1131. In some implementations, both the doped and undoped initial semiconductor bodies 1001 may be etched, and depth of the ion implantation may be located over the top surface of the conductive layer 1131, so that the doped portion has a faster etching rate, and the doped initial semiconductor body 1001 first reaches a target etching depth compared to the undoped initial semiconductor body. In some implementations, as shown in FIG. 18, the isolation material 141 on the initial semiconductor body 1001 in FIG. 17 is removed, and a first dielectric layer 101 is formed. Composition materials of the first dielectric layer 101 and the isolation material 141 may be the same or different. The first dielectric layer 101 has an opening 194 that exposes the initial semiconductor body 1001. The initial semiconductor body 1001 exposed by the opening 194 is etched, and the ion-implanted initial semiconductor body 1001 is removed to form the first semiconductor body 1111, and the first opening 191 is formed on the first semiconductor body 1111. The non-ion-implanted initial semiconductor body 1001 forms the second semiconductor body 1112 due to its slow etching rate or being substantially unetched. The second semiconductor body 1112 has a top surface higher than the top surface of the first semiconductor body 1111 due to being less etched or substantially unetched.

In some implementations, as shown in FIG. 19, the method for forming the first dielectric layer 1121 includes etching and removing the dielectric layer 1120 exposed on sidewalls at the bottom of the first opening 191 to form the second opening 192. The conductive layer 1131 is exposed on sidewalls at the bottom of the second opening 192 in the x-direction, and the etched dielectric layer 1120 forms the first dielectric layer 1121.

In some implementations, as shown in FIG. 23, the method for forming the first contact structure 161 includes filling a conductive material in the second opening 192 to form the first contact structure 161. In some implementations, as shown in FIG. 23, the manufacturing method further comprises: forming a second contact structure 162 on the first end of the second semiconductor body 1112, wherein the bottom of the second contact structure 162 is connected to the first end of the second semiconductor body 1112. As shown in FIG. 23, a conductive material is filled into the second opening 192 as shown in FIG. 19 to form the first contact structure 161, and a conductive material is filled into the opening 194 on the second semiconductor body 1112 as shown in FIG. 19 to form the second contact structure 162. The filling process of the conductive materials may include but is not limited to chemical deposition, physical deposition, electroplating, or a combination thereof.

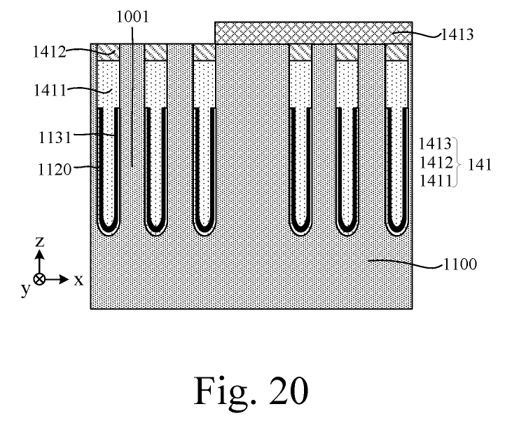

In some implementations, as shown in FIG. 20, the isolation material 141 is filled into the trench 190 in FIG. 16 and a trench extending along the x-direction which is not shown. The isolation material 141 covers the dielectric layer 1120 and the conductive layer 1131, and may cover the top surface of the initial semiconductor body 1001. The isolation material 141 is a dielectric material, and may include a plurality of dielectric materials, i.e., the first isolation material 1411, the second isolation material 1412, and the third isolation material 1413, as shown in FIG. 20, in which the first isolation material 1411, the second isolation material 1412, and the third isolation material 1413 may be the same or different. In FIG. 20, the first isolation material 1411 and the second isolation material 1412 are located between the adjacent initial semiconductor bodies 1001, the second isolation material 1412 is located over the first isolation material 1411, the top surface of the first isolation material 1411 is flush with the top surface of the initial semiconductor body 1001, and the third isolation material 1413 covers a portion of the initial semiconductor body 1001. The second isolation material 1412 has the same material as the first dielectric layer 101 shown in FIG. 2 and the first dielectric layer 101 illustrated in FIGS. 7, 8, and 18.

In some implementations, the method for forming the first semiconductor body 1111 includes: as shown in FIG. 20, removing a portion of the third isolation material 1413 on a portion of the initial semiconductor body 1001 to expose a first end of the portion of the initial semiconductor body 1001; and, using the third isolation material 1413 as a doping mask, ion implanting the initial semiconductor body 1001 exposed in FIG. 20 along the z-direction, wherein the depth of ion implantation is lower than the top surface of the conductive layer 1131 to accelerate the etching rate of the doped semiconductor material.

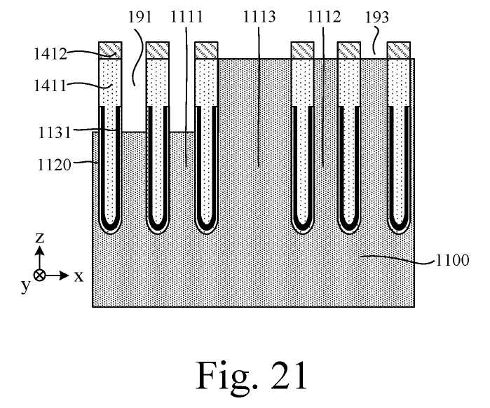

As shown in FIG. 21, after the ion implantation, the third isolation material 1413 covering the initial semiconductor body 1001 in FIG. 20 is removed, and the initial semiconductor body 1001 is etched. The doped initial semiconductor body 1001 has a faster etching rate. The exposed initial semiconductor body 1001 is etched to form first openings 191 arranged along the x-direction and y-direction. The sidewalls at the bottom of the first opening 191 exposes a portion of the dielectric layer 1120 in the x-direction, and the etched initial semiconductor body 1001 forms the first semiconductor body 1111. The first opening 191 is located over the first end of the first semiconductor body 1111.

As shown in FIG. 21, when forming the first opening 191, the non-ion-implanted initial semiconductor body 1001 may also be etched to form the second semiconductor body 1112, with an etching amount smaller than that of the ion-implanted initial semiconductor body 1001. The third opening 193 is formed over the second semiconductor body 1112, and the depth of the third opening 193 in the z-direction is smaller than that of the first opening 191 in the z-direction.

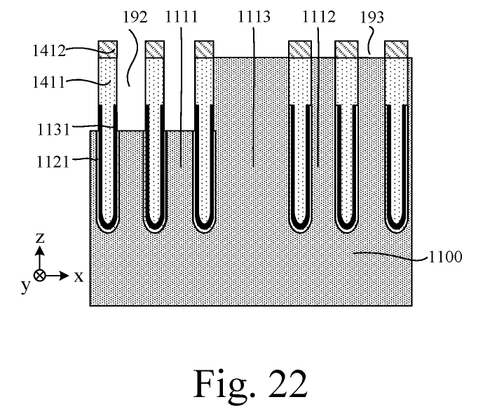

In some implementations, as shown in FIG. 22, the dielectric layer 1120 exposed on the sidewalls at the bottom of the first opening 191 in FIG. 21 is etched and removed to form the second opening 192, and sidewalls at the bottom of the second opening 192 exposes the conductive layer 1131 in the x-direction.

In some implementations, as shown in FIG. 23, a conductive material is filled into the second opening 192 to form the first contact structure 161, and a conductive material is filled into the third opening 193 to form the second contact structure 162.

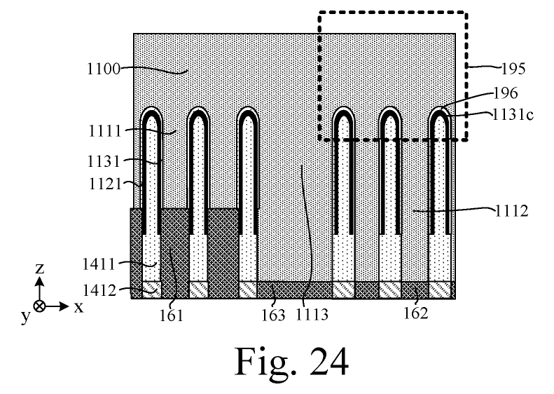

In some implementations, as shown in FIGS. 23 and 24, the conductive layer 1131 includes: a first portion 1131a and a second portion 1131b extending along the z-direction, wherein the first portion 1131a and the second portion 1131b are disposed at intervals in the x-direction; and a third portion 1131c located between the first portion 1131a and the second portion 1131b in the x-direction, wherein the third portion 1131c is located at an end of the first portion 1131a and the second portion 1131b away from the first contact structure 161, and connects the first portion 1131a and the second portion 1131b.

The manufacturing method further includes: etching the conductive layer 1131 between the adjacent second semiconductor bodies 1112, removing the third portion 1131c of the conductive layer 1131, and removing the first portion 1131a and the second portion 1131b on sidewalls of the second end of the second semiconductor body 1112, thus forming a plurality of gate layers 1132 disposed at intervals, wherein the gate layer 1132 covers the sidewalls extending along the x-direction between the first and second ends of the second semiconductor body 1112.

As shown in FIG. 23, the shape of the cross-section of the conductive layer 1131 located between the two adjacent semiconductor bodies 1101 in the xoz plane is U-shaped or nearly U-shaped. The first and second portions of the conductive layer 1131 are side faces of the conductive layer 1131 extending along the z-direction, covering sidewalls of the two adjacent first semiconductor bodies 1111, respectively. The third portion 1131c is located at the bottom of the conductive layer 1131, and connects the first portion 1131a and the second portion 1131b. The third portion 1131c may be a straight line shape extending along the x-direction, or an arc shape protruding towards or away from the first contact structure 161, or other irregular shapes with protrusions or bulges. Composition materials of the three portions of the conductive layer 1131 may be the same, and the three portions form a whole. As shown in FIG. 24, the first semiconductor structure 11 in FIG. 23 may be flipped upside down, and the third portion 1131c of the conductive layer 1131 located on the second semiconductor body 1112 may be removed along the backside of the semiconductor strip 1100 to break one conductive layer 1131 and form two separate gate layers 1132.

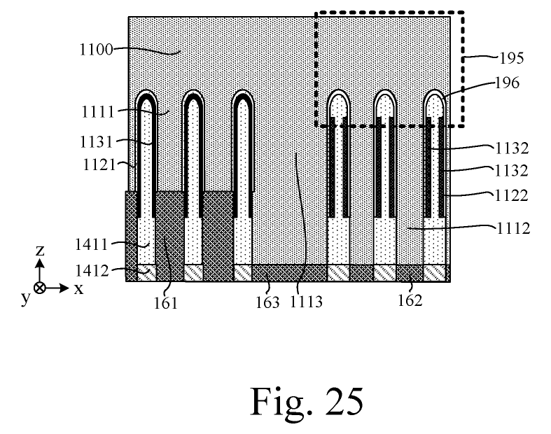

In some implementations, as shown in FIG. 24, second ends of a plurality of initial semiconductor bodies 1001 arranged along the x-direction are connected to each other. For example, the second ends of the plurality of initial semiconductor bodies 1001 are connected to the semiconductor strip 1100, which extends along the x-direction. The manufacturing method further comprises: forming a first trench 195 extending along the x-direction on a side of the second end of the second semiconductor body 1112, wherein the first trench 195 is located between the second ends of the second semiconductor bodies 1112 that are adjacent in the y-direction, and may expose at least the conductive layer 1131 at the second end of the second semiconductor body 1112; and, as shown in FIG. 25, removing the exposed portion of the conductive layer 1131 (the third portion 1131c of the conductive layer 1131) based on the first trench 195 to form the gate layer 1132.

In FIG. 24, the position of the first trench 195 is obscured due to the cross-sectional direction. The position of the dashed box in the figure illustrates an extension direction of the first trench 195, which is located between two second semiconductor bodies 1112 that are adjacent in the y-direction. The first trench 195 does not extend to the area where the first semiconductor body 1111 is located. In FIG. 24, a dielectric material or isolation material filled at the second end of the second semiconductor body 1112 is etched along the back of the semiconductor strip 1100 to form the first trench 195. When forming the first trench 195, the dielectric material or the dielectric layer 1120 between the third portion 1131c of the conductive layer 1131 and the unbroken semiconductor material (the semiconductor strip 1100) in FIG. 24 is also removed to form a first cavity 196. The first cavity 196 may be a portion of the first trench 195 extending between the conductive layer 1131 and the second semiconductor body 1112, such that the third portion 1131c of the conductive layer 1131 is exposed from the first trench 195. Alternatively, the first cavity 196 may be formed by performing other etching processes and is not a part of the first trench 195. The first cavity 196 is connected to the first trench 195, so that the third portion 1131c of the conductive layer 1131 is exposed from the first trench 195 through the first cavity 196.

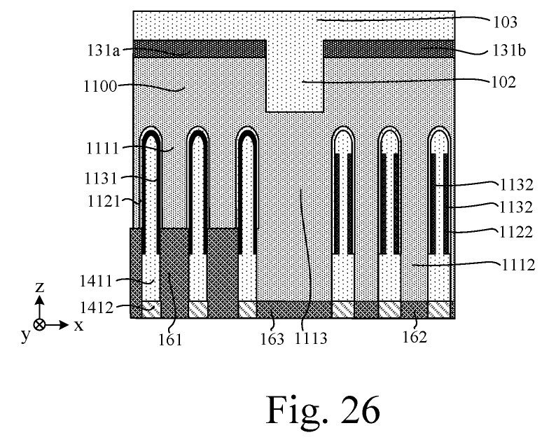

In FIG. 25, an etchant, such as a wet etchant, is introduced through the first trench 195 to etch the third portion 1131c of the conductive layer 1131 exposed at the bottom of the first trench 195. The etchant enters the first cavity 196 to etch the exposed third portion 1131c of the conductive layer 1131, so that one conductive layer 1131 forms two gate layers 1132 in face-to-face configuration. As shown in FIG. 26, the first trench 195 and the first cavity 196 are filled with a dielectric material.

In some implementations, the backside of the semiconductor strip 1100 may be thinned before forming the first trench 195, and the thinning process may include but is not limited to etching or chemical mechanical polishing.

In some implementations, as shown in FIG. 26, the manufacturing method further includes: forming the bit line 131 based on a connection portion of the second end of the initial semiconductor body (such as the semiconductor strip 1110). At least a portion of the semiconductor strip 1100 forms the bit line 131, and at least a portion of the bit line 131 is connected to the second end of the second semiconductor body 1112. For example, the semiconductor strip 1100 may be doped heavily to form the bit line 131, or the semiconductor strip 1100 may be metalized to form a metal silicide to form the bit line 131, or a metal may be deposited on the metal silicide to form the bit line 131, or a metal may be deposited directly on the semiconductor strip 1100 to form the bit line 131.

The first contact structure 161 uses the conductive layer 1131 for leading out, instead of using the bit line 131 and the semiconductor body 1101. The bit line 131 may not be disposed on a side of the first semiconductor body 1111 away from the first contact structure 161. As shown in FIG. 26, in order to reduce the manufacturing process, a continuous bit line 131 is disposed on a side of the first semiconductor body 1111 and the second semiconductor body 1112 away from the contact structure 160, and a first isolation structure 102 extending in the y-direction is formed at the junction of the first semiconductor body 1111 and the second semiconductor body 1112 to break the bit line 131, thus forming a first bit line 131a corresponding to the first semiconductor body 1111, and a second bit line 131b corresponding to and electrically connected to the second semiconductor body 1112. The first bit line 131a is not electrically interconnected with the first semiconductor body 1111, and the first bit line 131a may not be provided with a connection structure for leading out. In some implementations, the first bit line 131a may be removed, leaving only the second bit line 131b.

In some implementations, as shown in FIGS. 23 to 25, the initial semiconductor body 1001 further comprises: a third semiconductor body 1101 located between the first semiconductor body 1111 and the second semiconductor body 1112 in the x-direction. In the x-direction, the semiconductor strip 1100 is connected to second ends of the first semiconductor body 1111, the second semiconductor body 1112, and the third semiconductor body 1113. The manufacturing method further includes: as shown in FIG. 26, forming a first isolation structure 102 on the second end of the third semiconductor body 1113, wherein the first isolation structure 102 extends along the y-direction, penetrates through the bit line 131 along the z-direction, and extends into the third semiconductor body 1113. The first isolation structure 102 divides the bit line 131 into a first bit line 131a and a second bit line 131b, in which the first bit line 131a corresponds to the second end of the first semiconductor body 1111, and the second bit line 131b is connected to the second end of the second semiconductor body 1112. A third contact structure 163 may or may not be disposed on the third semiconductor body 1113. The third contact structure 163 is a dummy contact structure and is not configured for coupling the device structures. The first isolation structure 102 may penetrate the semiconductor strip 1100.

In FIG. 26, the manufacturing method of the first isolation structure 102 may include: forming the bit line 131 based on the semiconductor strip 1100 in FIG. 25, etching the bit line 131 and the semiconductor strip 1100, forming a trench extending along the y-direction, and filling the trench with a dielectric material to form the first isolation structure 102. The dielectric material may cover the bit line 131, and the dielectric material covering the bit line 131 may be referred to as the first dielectric material 103.

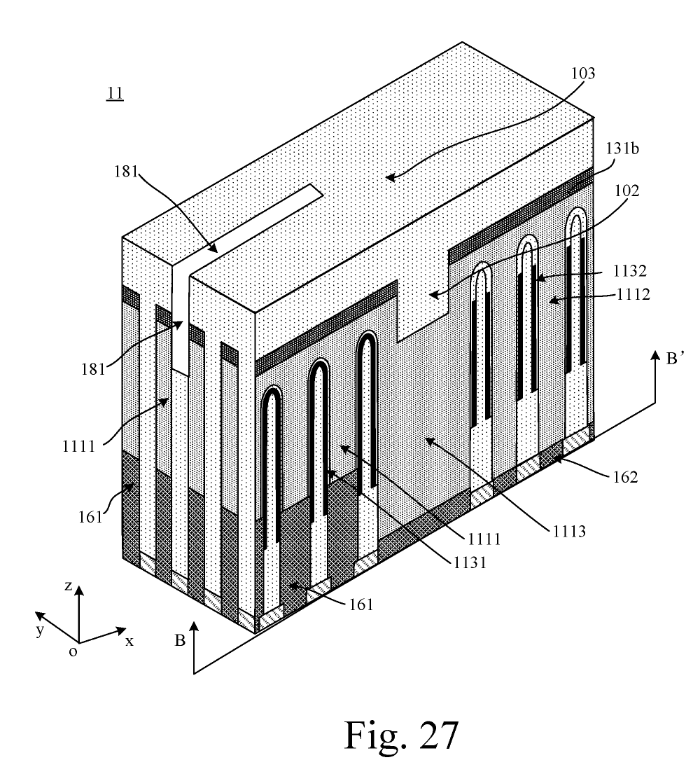

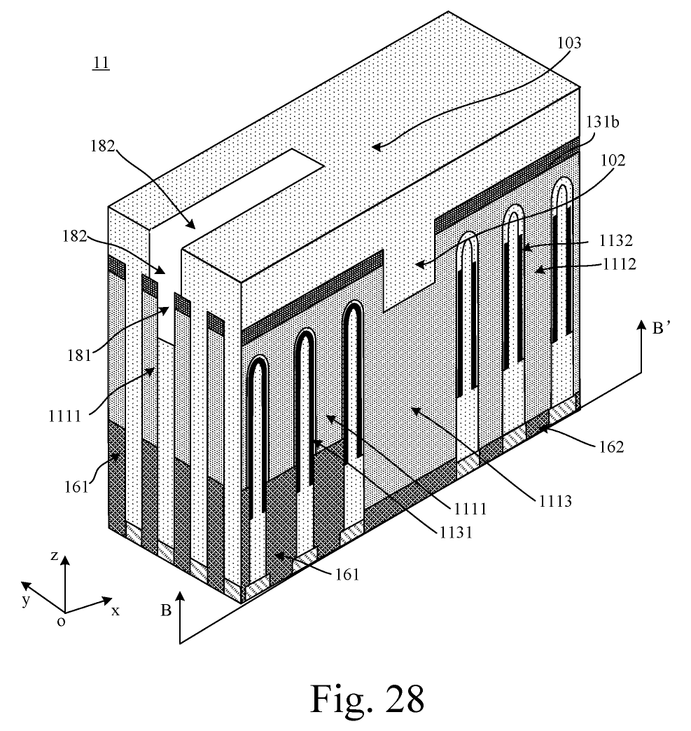

In some implementations, the manufacturing method further comprises: as shown in FIG. 27, forming the first dielectric material 103 at least over the second end of the first semiconductor body 1111, wherein the first dielectric material 103 covers at least the second end of the first semiconductor body 1111; and etching the first dielectric material 103 to form a second trench 181 extending along the x-direction, wherein the second trench 181 extends along the z-direction between the first semiconductor bodies 1111 that are adjacent in the y-direction, the bottom of the second trench 181 exposes the conductive layer 1131, and the first connection structure 171 is formed at least in the second trench 181. The second trench 181 in FIG. 27 may be filled with a conductive material to form the first connection structure 171. Alternatively, an opening end of the second trench 181 may be expanded to increase its size, and the expanded second trench may be filled to form the first connection structure 171 as shown in FIG. 28.

In some implementations, as shown in FIG. 28, the first dielectric material 103 at the opening end of the second trench 181 is etched to form a third trench 182. The third trench 182 is located over the second end of the first semiconductor body 1111 and is connected to the second trench 181. The size of the third trench 182 in the y-direction is larger than the size of the second trench 181 in the y-direction. A conductive material is filled in the third trench 182 and the second trench 181 to form the first connection structure 171 as shown in FIG. 9. The cross-sectional structures taken at BB' in FIGS. 27 and 28 may include the structure as shown in FIG. 26.

The second trench 181 and the third trench 182 do not extend along the x-direction to the region where the gate layer 1132 is located. For example, in FIG. 27, the second trench 181 and the third trench 182 may extend on a side of the first isolation structure 102 away from the second bit line 131b in the x-direction, or the second trench 181 may extend into the first isolation structure 102 but not penetrate the first isolation structure 102 along the x-direction. The second trench 181 may extend downward along the z-direction, thus exposing sidewalls of the conductive layer 1131 along the z-direction.

In some implementations, the second semiconductor body 1112 in FIGS. 23 to 28 may be etched along the z-direction to divide one second semiconductor body 1112 into two semiconductor bodies 1101, such that one gate layer 1103 corresponds to one semiconductor body 1101, and a conductive structure as shown in FIG. 12 may be formed between two new second semiconductor bodies 1112.

In some implementations, the first capacitor structure 121 and the second capacitor structure 122 as shown in FIG. 12 are formed on the first contact structure 161 and the second contact structure 162 as shown in FIG. 9, and the second semiconductor structure 21 is bonded to a side of the bit line 131 away from the capacitor structure 120. A solder pad 135 is formed on a side of the capacitor structure 120 away from the bit line 131. The solder pad 135 may be used as an IO interface to power and communicate with the semiconductor device 10.

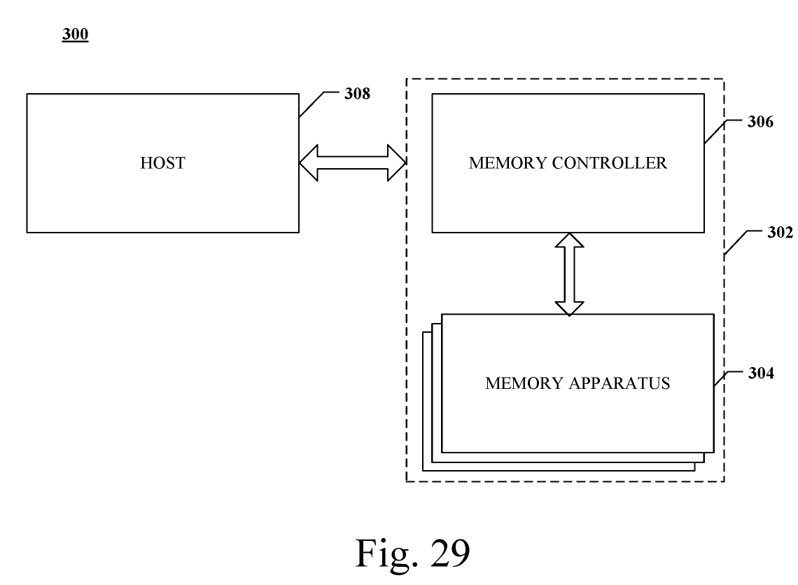

According to some aspects of implementations of the present disclosure, a memory system 302 is provided, comprising: one or more semiconductor devices 10 provided in the present disclosure; and a memory controller 306 coupled to and controlling the semiconductor devices 10. FIG. 29 provides a memory system 302, which includes a memory apparatus 304 and a memory controller 306 coupled to and controlling the memory apparatus 304. The memory apparatus 304 includes the semiconductor device 10 (or the memory device) as shown in FIGS. 2 to 4 and FIGS. 11 to 13. The semiconductor device 10 is the memory apparatus 304 or at least a part of the memory apparatus 304.

As shown in FIG. 29, an implementation of the present disclosure provides a system 900 comprising a host 308. The system 900 may be a mobile phone, graphics processing device, desktop computer, laptop computer, tablet computer, vehicle computer, game console, printer, positioning device, wearable electronic device, smart sensor, virtual reality (VR) device, augmented reality (AR) device, or any other suitable electronic device with storage. As shown in FIG. 29, the system 900 may include a host 308 and a memory system 302. The memory system 302 has one or more memory apparatuses 304 and a memory controller 306. The host 308 may be a processor of an electronic device, such as a central processing unit (CPU), or a system on chip (SoC), such as an application processor (AP). The host 308 may be configured to send data to or receive data from the memory apparatus 304. The memory apparatus 304 may include the semiconductor device 10 disclosed herein.

According to some implementations, the memory controller 306 is coupled to the memory apparatus 304 and the host 308, and configured to control the memory apparatus 304 to perform read, write, or refresh operations. The memory controller 306 may manage data stored in the memory apparatus 304 and communicate with the host 308. The memory apparatus 304 includes a DRAM, or a package structure formed by stacking a plurality of DRAMs, and may be applied to HBM or HMC package structures.

In some examples, the HBM package structure may include vertically stacking a plurality of DRAM chips on a logic chip, with an electrical interconnection between the logic chip and the plurality of DRAM chips being made through a through silicon via (TSV). The plurality of DRAM chips and the logic chip may be considered as a memory system, in which the logic chip may include but is not limited to a control logic, interface control module, SRAM cache, and other components, the logic chip may be configured as the memory controller 306, and the semiconductor device 10 may be configured as the memory apparatus 304 or DRAM chip. The HBM package structure may also include processor chips such as GPU, CPU, or SOC chips. A memory controller may be integrated in the processor to control data transmission of the DRAM chips. For example, the processor such as GPU, etc., is coupled with the logic chip to exchange data with the DRAM through the logic chip. In some other examples, the Hybrid Memory Cube (HMC) package structure may include vertically stacking a plurality of DRAM chips on a logic chip, with an electrical interconnection between the logic chip and the plurality of DRAM chips being made through TSV. The plurality of DRAM chips and the logic chip may be considered as a memory system, in which the logic chip may include but is not limited to a control logic, interface control module, SRAM cache, and other components. The logic chip may integrate a memory controller.

In some examples, the memory system 302 may be used as an auxiliary in solid-state drives, which may bring improvements in read and write to solid-state drives. Some high-end solid-state drive products often choose to embed a DRAM to enhance product performance and improve random read and write speed. For example, when writing files, especially small files, small files are processed by a DRAM and then stored in a flash memory, making solid-state drive storage more efficient and faster. A flash includes a non-volatile memory, including but not limited to 2D NAND memory or 3D NAND memory. In some examples, the memory system 302 may use a caching device as a graphics processing core (GPU) in a graphics processing device, which may include but is not limited to a graphics card.

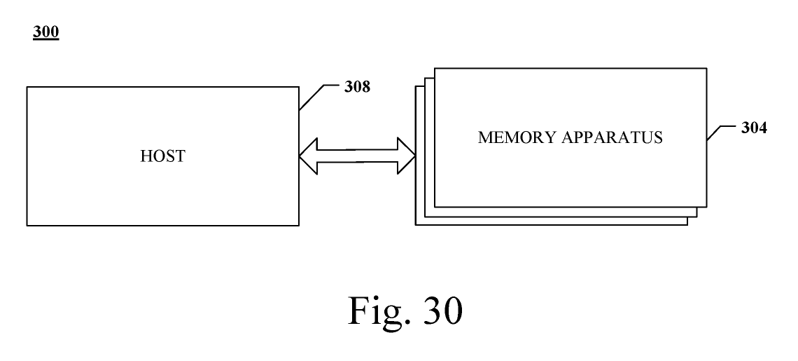

In some other implementations, as shown in FIG. 30, the system 900 may only include a host 308 and a memory apparatus 304 coupled to the host 308. A controller that controls the memory apparatus 304 may be located inside the host 308, such as a memory controller integrated into a central processing unit (CPU), or a southbridge or northbridge chip integrated into the motherboard of the system 900. The memory apparatus 304 may include but is not limited to: double data rate synchronous dynamic random access memory with DDR4 memory specification or DDR5 memory specification, and low-power consumption double data rate synchronous dynamic random access memory using LPDDR5 memory specification. The memory apparatus 304 may include a semiconductor device 10.

In some implementations provided in the present disclosure, it should be understood that the disclosed devices and methods may be implemented in a non-targeted manner. The device implementations described above are only illustrative. For example, the division of units is only a logical functional division. In practical implementations, there may be other division methods, e.g., a plurality of cells or components may be combined, or may be integrated into another system, or some features may be ignored or not executed. In addition, the direct or indirect coupling between various components displayed or discussed. The methods disclosed in several method implementations provided in the present disclosure may be combined arbitrarily without conflict to obtain a new method implementation.

The above are only implementations of the present disclosure, but the scope of the present disclosure is not limited to this. Any person skilled in the art may easily conceive of changes or substitutions within the scope of the technology disclosed in the present disclosure, which should be included in the scope of the present disclosure.

What is claimed is:

1. A semiconductor device comprising:
first semiconductor bodies extending along a first direction, wherein a first semiconductor body of the first semiconductor bodies has a first end and a second end arranged opposite to each other along the first direction;
conductive layers extending along a second direction, wherein a conductive layer of the conductive layers is located between the first semiconductor bodies that are adjacent in a third direction, the second direction intersects with the third direction, and a plane formed by the second direction and the third direction intersects with the first direction; and
a first contact structure located on a side close to the first end of the first semiconductor body in the first direction,
wherein an end of the first contact structure close to the first semiconductor body is located between adjacent ones of the conductive layers, and
wherein sidewalls of the first contact structure extending along the first direction overlap at least partially with the conductive layer in the third direction, and are connected to the conductive layer.

2. The semiconductor device of claim 1, wherein the semiconductor device further comprises:
a first dielectric layer located between the first semiconductor body and the conductive layer, wherein the conductive layer is close to an end of the first contact structure and protrudes from the first dielectric layer in the first direction towards the first contact structure.

3. The semiconductor device of claim 2, wherein the first contact structure covers the first dielectric layer in the first direction, and the first dielectric layer is close to a surface of the first contact structure in the first direction, and is flush with a surface of the first end of the first semiconductor body.

4. The semiconductor device of claim 3, wherein the first direction and the third direction constitute a first plane, and a cross section of the conductive layer on the first plane comprises:
a first portion and a second portion extending along the first direction, wherein the first portion and the second portion are disposed at intervals in the third direction; and
a third portion located between the first portion and the second portion in the third direction, wherein the third portion is located at an end of the first portion and the second portion away from the first contact structure, and connects the first portion and the second portion.

5. The semiconductor device of claim 1, wherein the semiconductor device further comprises:
a first connection structure that extends along the third direction and is located on a side of the conductive layer away from the first contact structure, wherein at least a portion of the first connection structure is located between two of the first semiconductor bodies that are adjacent in the second direction, and the first connection structure is connected to the conductive layer.

6. The semiconductor device of claim 5, wherein the first connection structure comprises: a first portion and a second portion that are connected,
wherein the first portion is located between two of the first semiconductor bodies that are adjacent in the second direction, and the first portion of the first connection structure overlaps partially with the first semiconductor body in the second direction, and
wherein the second portion of the first connection structure is located on a side of the second end of the first semiconductor body away from the first contact structure, and a size of the second portion in the second direction is larger than a size of the first portion in the second direction.

7. The semiconductor device of claim 2, wherein the semiconductor device further comprises:
second semiconductor bodies extending along the first direction, wherein a second semiconductor body of the second semiconductor bodies has a first end and a second end arranged opposite to each other along the first direction; and
a second contact structure located on a side close to the first end of the second semiconductor body in the first direction, wherein the second contact structure is connected to the first end of the second semiconductor body,
wherein a size of the second semiconductor body in the first direction is larger than a size of the first semiconductor body in the first direction, a size of the second contact structure in the first direction is smaller than a size of the first contact structure in the first direction, and the first end of the second semiconductor body overlaps partially with the first contact structure in the third direction.

8. The semiconductor device of claim 7, wherein the semiconductor device further comprises:
a gate layer extending along the second direction, wherein the gate layer is located between the second semiconductor bodies that are adjacent in the third direction, and is located on a side of the second semiconductor body in the third direction;
a second dielectric layer located between the second semiconductor body and the gate layer, wherein a size of the second dielectric layer in the first direction is larger than a size of the first dielectric layer in the first direction; and
at least one bit line extending along the third direction, wherein at least a portion of the at least one bit line is connected to the second end of the second semiconductor body.

9. The semiconductor device of claim 8, wherein the at least one bit line comprises a first bit line and a second bit line, the first bit line corresponds to a second end of the first semiconductor body, and the second bit line is connected to the second end of the second semiconductor body, and
wherein the semiconductor device further comprises:
a third semiconductor body located between the first semiconductor body and
the second semiconductor body in the third direction,; and
a first isolation structure extending along the second direction, wherein the first
isolation structure is located at an end of the third semiconductor body away from the first contact structure in the first direction, and the first isolation structure is located between the first bit line and the second bit line, and isolates the first bit line from the second bit line.

10. The semiconductor device of claim 8, wherein the semiconductor device further comprises:
a peripheral circuit, wherein the peripheral circuit is coupled to at least the conductive layer, the gate layer, and the bit line;
a first capacitor structure connected to the first contact structure; and
a second capacitor structure connected to the second contact structure and configured as a storage capacitor.

11. A manufacturing method of a semiconductor device, comprising:
forming first semiconductor bodies extending along a first direction, wherein a first semiconductor body of the first semiconductor bodies has a first end and a second end arranged opposite to each other along the first direction;
forming conductive layers extending along a second direction, wherein a conductive layer of the conductive layers is located between the first semiconductor bodies that are adjacent in a third direction, the conductive layer protrudes from the first end along the first direction, the second direction intersects with the third direction, and a plane formed by the second direction and the third direction intersects with the first direction; and
forming a first contact structure on the first end of the first semiconductor body, wherein an end of the first contact structure close to the first semiconductor body is located between adjacent ones of the conductive layers, and sidewalls of the first contact structure extending along the first direction are connected to the conductive layer.

12. The manufacturing method of claim 11, wherein the manufacturing method further comprises:
forming a first dielectric layer between the first semiconductor body and the conductive layer, wherein a top surface of the first dielectric layer in the first direction is lower than that of the conductive layer.

13. The manufacturing method of claim 12, wherein forming the conductive layer comprises:
providing a plurality of initial semiconductor bodies extending along the first direction, wherein an initial semiconductor body of the plurality of initial semiconductor bodies has a first end and a second end arranged opposite to each other in the first direction, and the plurality of initial semiconductor bodies include at least a second semiconductor body; and
forming a dielectric layer and the conductive layer between adjacent ones of the plurality of initial semiconductor bodies, wherein the dielectric layer is located between the initial semiconductor body and the conductive layer, and the conductive layer covers a portion of sidewalls of the initial semiconductor body extending along the first direction.

14. The manufacturing method of claim 13, wherein forming the first semiconductor body comprises:
etching a portion of the initial semiconductor body to form a first opening,
wherein sidewalls at a bottom of the first opening exposes a portion of the dielectric layer in the third direction, the etched portion of the initial semiconductor body forms the first semiconductor body, and the first opening is located over the first end of the first semiconductor body,
wherein forming the first dielectric layer comprises:
etching and removing the dielectric layer exposed on the sidewalls at the bottom
of the first opening to form a second opening, wherein sidewalls at a bottom of the second opening exposes the conductive layer in the third direction, and the etched dielectric layer forms the first dielectric layer, and
wherein forming the first contact structure comprises:
filling the second opening with a conductive material to form the first contact
structure.

15. The manufacturing method of claim 14, wherein the manufacturing method further comprises:
forming a second contact structure on the first end of the second semiconductor body, wherein a bottom of the second contact structure is connected to the first end of the second semiconductor body.

16. The manufacturing method of claim 13, wherein the manufacturing method further comprises:
ion implanting, along the first direction, the initial semiconductor body in which the first semiconductor body is to be formed,
wherein a depth of ion implantation is lower than a top surface of the conductive layer.

17. The manufacturing method of claim 13, wherein the conductive layer comprises:
a first portion and a second portion extending along the first direction, wherein the first portion and the second portion are disposed at intervals in the third direction; and
a third portion located between the first portion and the second portion in the third direction, wherein the third portion is located at an end of the first portion and the second portion away from the first contact structure, and connects the first portion and the second portion, and
wherein the manufacturing method further comprises:
etching the conductive layer between adjacent ones of the second
semiconductor bodies, removing the third portion of the conductive layer, and removing the first portion and the second portion on sidewalls of the second end of the second semiconductor body to form a plurality of gate layers disposed at intervals, wherein a gate layer of the plurality of gate layers covers sidewalls extending along the first direction between the first end and the second end of the second semiconductor body.

18. The manufacturing method of claim 17, wherein the manufacturing method further comprises:
forming a bit line based on a connection portion of the second end of the initial semiconductor body, wherein at least a portion of the bit line is connected to the second end of the second semiconductor body, wherein the initial semiconductor body further comprises: a third semiconductor body located between the first semiconductor body and the second semiconductor body in the third direction; and
forming a first isolation structure on a second end of the third semiconductor body, wherein the first isolation structure extends along the second direction, penetrates through the bit line along the first direction, and extends into the third semiconductor body,
wherein the first isolation structure divides the bit line into a first bit line and a second bit line, wherein the first bit line corresponds to the second end of the first semiconductor body, and the second bit line is connected to the second end of the second semiconductor body.

19. The manufacturing method of claim 11, wherein the manufacturing method further comprises:
forming a first dielectric material at least over the second end of the first semiconductor body, wherein the first dielectric material covers at least the second end of the first semiconductor body;
etching the first dielectric material to form a second trench extending along the third direction, wherein the second trench extends between the first semiconductor bodies that are adjacent in the second direction along the first direction, and a bottom of the second trench exposes the conductive layer; and
forming a first connection structure at least in the second trench.

20. A memory system comprising:
a semiconductor device, the semiconductor device comprising:
first semiconductor bodies extending along a first direction, wherein a first semiconductor body of the first semiconductor bodies has a first end and a second end arranged opposite to each other along the first direction;
conductive layers extending along a second direction, wherein a conductive layer of the conductive layers is located between the first semiconductor bodies that are adjacent in a third direction, the second direction intersects with the third direction, and a plane formed by the second and third directions intersects with the first direction; and
a first contact structure located on a side close to the first end of the first semiconductor body in the first direction,
wherein an end of the first contact structure close to the first semiconductor body is located between adjacent ones of the conductive layers, and sidewalls of the first contact structure extending along the first direction overlap at least partially with the conductive layer in the third direction, and are connected to the conductive layer; and
a memory controller coupled to and configured to control the semiconductor device.
